(19) United States
(12) Patent Application Publication
(10) Pub. No.: US 2024/0030390 A1
(43) Pub. Date: Jan. 25, 2024

(54) DISPLAY DEVICE AND METHOD OF FABRICATING THE SAME

(71) Applicant: Samsung Display Co., LTD., Yongin-si (KR)

(72) Inventors: Dong Hyun KIM, Yongin-si (KR); Min Jun JANG, Yongin-si (KR)

(73) Assignee: Samsung Display Co., LTD., Yongin-si (KR)

(21) Appl. No.: 18/119,491

(22) Filed: Mar. 9, 2023

(30) Foreign Application Priority Data
Jul. 19, 2022 (KR) 10-2022-0089208

(51) Int. Cl. H01L 33/54; H01L 25/16; H01L 33/58

(52) U.S. Cl. CPC H01L 33/54; H01L 25/167; H01L 33/58; H01L 2933/0058; H01L 2933/005; H01L 24/29

(57) ABSTRACT

A display device includes a display panel including a display area in which pixels are provided, and a non-display area located on a side of the display area, a circuit board bonded to the display panel in the non-display area, and electrically connected to the pixels, an optical layer provided on the display panel in the display area, and a protective layer disposed on the display panel in the non-display area. A top surface of the protective layer includes a protrusion having an island shape, or a trace formed by removing at least a portion of the protrusion.

### CROSS-REFERENCE TO RELATED APPLICATION(S)

The application claims priority to and benefits of Korean patent application number 10-2022-0089208, filed on Jul. 19, 2022, in the Korean Intellectual Property Office (KIPO), the entire contents of which are incorporated herein by reference.

### BACKGROUND

### 1. Technical Field

Various embodiments of the disclosure relate to a display device and a method of fabricating the display device.

### 2. Description of Related Art

With an increase in interest in an information display and an increase in demand to use portable information media, demand for display devices is markedly increased, and commercialization thereof is in progress.

### SUMMARY

Various embodiments of the disclosure are directed to a display device having enhanced reliability, and a method of fabricating the display device.

The objects of the disclosure are not limited to the above-stated object, and those skilled in the art will clearly understand other not mentioned objects from the accompanying claims.

An embodiment of the disclosure provides a display device that may include a display panel including a display area in which pixels are provided, and a non-display area located on a side of the display area, a circuit board bonded to the display panel in the non-display area, and electrically connected to the pixels, an optical layer provided on the display panel in the display area, and a protective layer disposed on the display panel in the non-display area. A top surface of the protective layer may include a protrusion having an island shape, or a trace formed by removing at least a portion of the protrusion.

The protective layer may include a resin. The optical layer may include an antireflection film.

The optical layer may be provided in the non-display area, and include a hole corresponding to the protrusion of the protective layer. The protective layer may be located between the optical layer and the display panel.

A diameter of the hole may be less than or equal to approximately 1 mm in a plan view.

The optical layer may contact the circuit board in the non-display area.

A side of the optical layer and a side of the display panel may be aligned with each other.

The display device may further include a dam disposed along a portion of a side of the display panel between the display panel and the optical layer. The protective layer may be located closer to a center of the display panel than the dam.

The dam may not overlap the circuit board, in a plan view.

The display device may further include a film provided on the display panel and the circuit board in the non-display area. The film may be located on a side of the optical layer, and differ from the optical layer.

The display device may further include a dam disposed along a portion of a side of the display panel between the display panel and the optical layer. The protective layer may be located closer to a center of the display panel than the dam.

The dam may include a resin or an adhesive tape.

A portion of the dam may overlap the circuit board, in a plan view.

The portion of the dam that overlaps the circuit board may be integrated with the circuit board.

The protective layer may be charged between the circuit board and the film.

The top surface of the protective layer and a top surface of the optical layer may be coplanar with each other.

The protective layer may include a light blocking material.

The display panel may include a display element layer including a light emitting element, and a light conversion pattern layer disposed on the display element layer and including a quantum dot changing a wavelength of light emitted from the light emitting element. The light conversion pattern layer may be formed through a continuous process on the display element layer.

The light emitting element may include an inorganic light emitting diode.

An embodiment of the disclosure provides a method of fabricating a display device that may include bonding circuit boards to a surface adjacent to at least one side of a display panel, forming a dam along a portion of a side of the display panel, disposing a mold on the display panel to cover the circuit board, applying a resin solution between the mold and the display panel through a hole formed in the mold, forming a protective layer between the mold and the display panel by curing the resin solution, and removing a protrusion formed on a top surface of the protective layer corresponding to the hole of the mold.

The method may further include attaching a film on the protective layer from which the protrusion is removed.

An embodiment of the disclosure provides a method of fabricating a display device that may include attaching an optical layer to a display panel to cover circuit boards bonded to a surface adjacent to at least one side of the display panel, applying a resin solution between the optical layer and the display panel through a gap between the circuit boards, and forming a protective layer between the optical layer and the circuit board by curing the resin solution.

A side of the optical layer and a side of the display panel may be aligned with each other.

Details of various embodiments are included in the detailed descriptions and drawings.

### BRIEF DESCRIPTION OF THE DRAWINGS

FIG. 1 is a diagram schematically illustrating a display device in accordance with an embodiment of the disclosure.

FIG. 2 is a schematic exploded perspective view illustrating the display device of FIG. 1.

FIG. 3 is a schematic plan view of the display device of FIG. 2.

FIG. 4 is a schematic cross-sectional view illustrating a display panel included in the display device of FIG. 3.

FIG. 5 is a schematic cross-sectional view taken along line II-II′ of FIG. 3.

FIG. 6 is a schematic cross-sectional view illustrating an embodiment of the display panel of FIG. 4.

FIG. 7 is a schematic cross-sectional view illustrating embodiments of a pixel circuit layer and a display element layer that are included in the display panel of FIG. 6.

FIG. 8 is a schematic cross-sectional view illustrating an embodiment of a display module taken along line I-I′ of FIG. 2.

FIG. 9 is a plan view illustrating the display module of FIG. 8.

FIGS. 10 and 11 are views for describing a method of fabricating the display module of FIG. 8.

FIG. 12 is a schematic cross-sectional view illustrating a comparative embodiment of a display module taken along line I-I′ of FIG. 2.

FIG. 13 is a plan view illustrating an embodiment of the display module of FIG. 9.

FIG. 14 is a schematic cross-sectional view taken along line III-III′ of FIG. 13.

FIG. 15 is a schematic cross-sectional view illustrating another embodiment of the display module taken along line I-I′ of FIG. 2.

FIGS. 16 and 17 are views for describing a method of fabricating the display module of FIG. 15.

FIG. 18 is a schematic cross-sectional view illustrating another embodiment of the display module taken along line I-I′ of FIG. 2.

FIG. 19 is a plan view illustrating the display module of FIG. 18.

FIG. 20 is a schematic cross-sectional view illustrating an embodiment of a second dam of FIG. 18.

FIGS. 21 to 24 are views for describing a method of fabricating the display module of FIG. 18.

FIG. 25 is a schematic cross-sectional view illustrating another embodiment of the display module taken along line I-I′ of FIG. 2.

FIG. 26 is a plan view illustrating the display module of FIG. 25.

### DETAILED DESCRIPTION OF THE EMBODIMENTS

As the disclosure allows for various changes and numerous embodiments, particular embodiments will be illustrated in the drawings and described in detail in the written description. However, this is not intended to limit the disclosure to particular modes of practice, and it is to be appreciated that all changes, equivalents, and substitutes that do not depart from the spirit and technical scope of the disclosure are encompassed in the disclosure.

Throughout the disclosure, like reference numerals refer to like parts throughout the various figures and embodiments of the disclosure. The sizes of elements in the accompanying drawings may be exaggerated for clarity of illustration. It will be understood that, although the terms “first”, “second”, etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

It will be further understood that the terms “comprise”, “include”, “have”, etc. when used in this specification, specify the presence of stated features, integers, steps, operations, elements, components, and/or combinations of them but do not preclude the presence or addition of one or more other features, integers, steps, operations, elements, components, and/or combinations thereof. Furthermore, in case that a first part such as a layer, a film, a region, or a plate is disposed on a second part, the first part may be not only directly on the second part but a third part may intervene between them.

When an element, such as a layer, is referred to as being “on”, “connected to”, or “coupled to” another element or layer, it may be directly on, connected to, or coupled to the other element or layer or intervening elements or layers may be present. When, however, an element or layer is referred to as being “directly on”, “directly connected to”, or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Embodiments and required details of the disclosure are described with reference to the accompanying drawings in order to describe the disclosure in detail so that those having ordinary knowledge in the technical field to which the disclosure pertains can readily practice the disclosure. Furthermore, a singular form may include a plural form as long as it is not specifically mentioned in a sentence.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

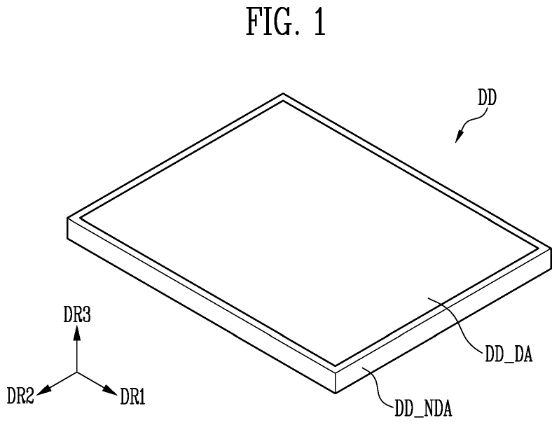

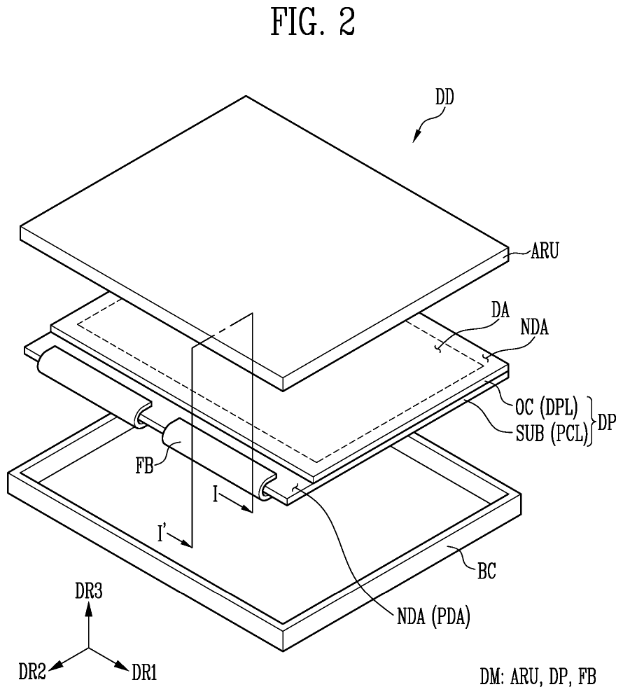

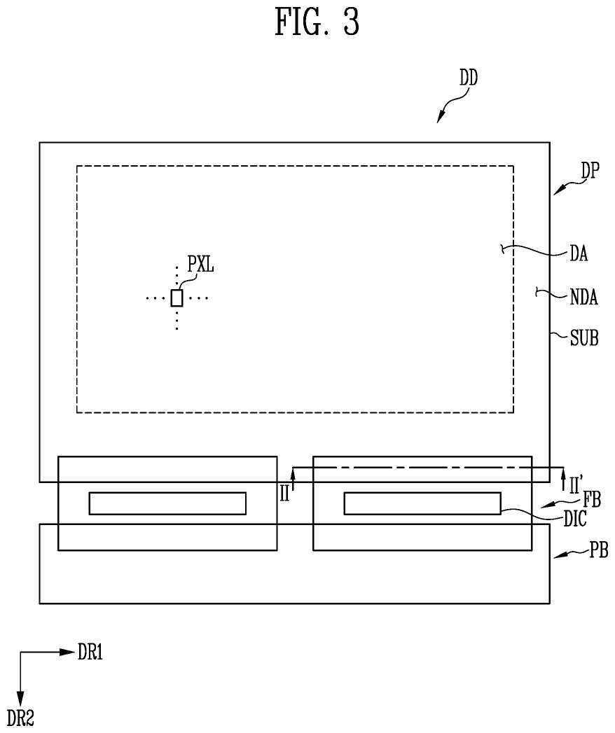

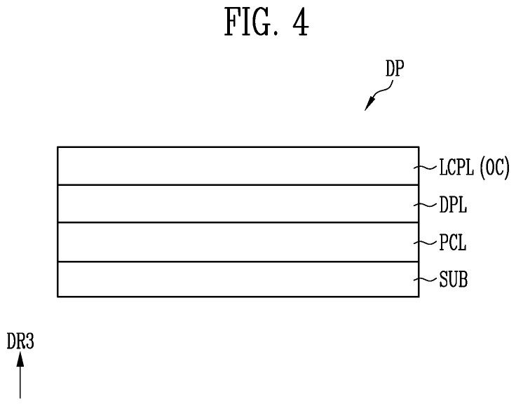

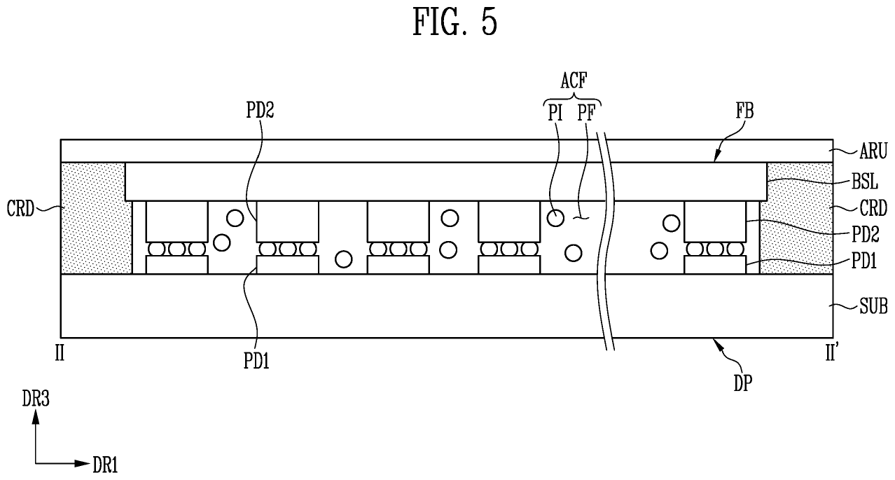

FIG. 1 is a diagram schematically illustrating a display device DD in accordance with an embodiment of the disclosure. FIG. 2 is a schematic exploded perspective view illustrating the display device DD of FIG. 1. FIG. 3 is a schematic plan view of the display device DD of FIG. 2. FIG. 4 is a schematic cross-sectional view illustrating a display panel DP included in the display device DD of FIG. 3. FIG. 5 is a schematic cross-sectional view taken along line II-II′ of FIG. 3.

Referring to FIGS. 1 to 5, the display device DD may display an image on a display surface, e.g., a display area DD_DA.

In case that the display device DD is an electronic device having a display surface on at least one surface thereof, e.g., a smartphone, a television, a tablet PC, a mobile phone, a video phone, an electronic reader, a desktop PC, a laptop PC, a netbook computer, a workstation, a server, a PDA, a portable multimedia player (PMP), an MP3 player, a medical appliance, a camera, or a wearable device, the disclosure may be applied to the display device DD.

The display device DD may be provided in various forms, for example, in the form of a rectangular plate having two pairs of parallel sides, but the disclosure is not limited thereto. In case that the display device DD is provided in the form of a rectangular plate, a pair of sides of the two pairs of sides may be longer than another pair of sides. Although in the drawing, each of the display devices DD has an angled corner formed by linear lines, the disclosure is not limited thereto. In an embodiment, in the display device DD provided in the form of a rectangular plate, a corner where a long side and a short side meet may have a round shape.

According to an embodiment of the disclosure, for the sake of explanation, the display device DD is illustrated as a rectangular form with a pair of long sides and a pair of short sides. The direction in which the long sides extend may be a first direction DR1, the direction in which the short sides extend may be a second direction DR2, and a thickness direction of the display device DD (or a substrate SUB) may be a third direction DR3.

In an embodiment of the disclosure, at least a portion of the display device DD may have flexibility, and the display device may fold at the portion having the flexibility.

The display device DD may include a display area DD_DA provided to display an image, and a non-display area DD_NDA provided on at least one side of the display area DD_DA. The non-display area DD_NDA may be an area on which an image is not displayed. However, the disclosure is not limited thereto. In an embodiment, the shape of the display area DD_DA and the shape of the non-display area DD_NDA may be designed to be relative to each other.

In an embodiment, the display device DD may include a sensing area and a non-sensing area. The display device DD may display an image through the sensing area and may also sense a touch input made on a display surface (or an input surface) or sense light that is incident from the front. The non-sensing area may enclose the sensing area, but the foregoing is merely for illustrative purposes, and the disclosure is not limited thereto. In an embodiment, a partial area of the display area DD_DA may correspond to the sensing area.

The display device DD may include a display module DM and a base casing BC (or a chassis, a frame, or the like).

The display module DM may be disposed in the base casing BC. The display module DM may include a display panel DP, a circuit board FB, and an optical layer ARU (or an optical film). Although FIGS. 2 and 3 illustrate that the number of circuit boards FB are two, the foregoing is merely for convenience of explanation, and the number of circuit boards FB is not limited thereto. For example, the display module DM may include three or more circuit boards FB.

The display panel DP may display an image. A self-emissive display panel, such as an organic light emitting display panel (OLED panel) using an organic light emitting diode as a light emitting element, a nano-LED or micro-LED display panel using an inorganic light emitting diode having a size ranging from a nanometer scale to a micrometer scale as a light emitting element, and a quantum dot organic light emitting display panel (QD OLED panel) using a light emitting diode such as a quantum dot, may be used as the display panel DP. A non-emissive display panel such as a liquid crystal display (LCD) panel, an electro-phoretic display (EPD) panel, or an electro-wetting display (EWD) panel may be also used as the display panel DP. In case that the non-emissive display panel is used as the display panel DP, the display device DD may include a separate light emitting element configured to supply light to the display panel DP.

The display panel DP may include a substrate SUB, and multiple pixels PXL (or sub-pixels) provided on the substrate SUB.

The substrate SUB (or a base layer) may be provided as an area having an approximately rectangular shape. However, the number of areas of the substrate SUB is not limited thereto. The shape of the substrate SUB may be changed depending on areas provided in the substrate SUB.

The substrate SUB may be made of insulating material such as glass or resin. The substrate SUB may be made of material having flexibility so as to be bendable or foldable, and have a single structure or a multilayer structure. For instance, examples of the material having flexibility may include polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, the material constituting the substrate SUB is not limited to that of the foregoing embodiments.

The substrate SUB may include a display area DA and a non-display area NDA. The display area DA may be an area in which the pixels PXL are provided and an image is thus displayed. The non-display area NDA may be an area in which the pixels PXL are not provided, and may be an area in which an image is not displayed. For the sake of explanation, FIG. 3 illustrates only one pixel PXL, but multiple pixels PXL may be provided in the display area DA of the substrate SUB. The display area DA of the substrate SUB (of the display panel DP) may correspond to the display area DD_DA of the display device DD. The non-display area NDA of the substrate SUB (or the display panel DP) may correspond to the non-display area DD_NDA of the display device DD. The non-display area NDA may correspond to a bezel area of the display device DD.

The non-display area NDA may be provided on at least one side of the display area DA. The non-display area NDA may enclose the perimeter (or edges) of the display area DA. A line component connected to the pixels PXL and a driver connected to the line component and configured to drive the pixels PXL may be provided in the non-display area NDA, but the disclosure is not limited thereto.

The line component may electrically connect the driver with the pixels PXL. The line component may be a fan-out line connected with signal lines, e.g., a scan line, and a data line, which are connected to each pixel PXL to provide signals to the pixel PXL.

Multiple first pads PD1 may be located on a surface of the substrate SUB. The first pads PD1 may be disposed in the non-display area NDA. The non-display area NDA in which the first pads PD1 are disposed may also be referred to as a pad component PDA (refer to FIG. 2).

The pixels PXL may be disposed in the display area DA of the substrate SUB. Each of the pixels PXL may be a smallest unit for displaying an image. Each of the pixels PXL may include a light emitting element which emits white light and/or color light. The color of each of the pixels PXL emit may be one of red, green, and blue, but the disclosure is not limited thereto, and the pixel PXL may emit light of a color such as cyan, magenta, or yellow.

The pixels PXL may be arranged in a matrix form along rows extending in the first direction DR1 and columns extending in the second direction DR2 intersecting with the first direction DR1. However, the arrangement of the pixels PXL is not limited to a particular arrangement. In other words, the pixels PXL may be arranged in various forms. Although each of the pixels PXL has been illustrated as having a rectangular shape, the disclosure is not limited thereto. The pixel PXL may have various shapes. In case that multiple pixels PXL are provided, the pixels PXL may have different surface areas (or different sizes). For example, in case that pixels PXL emit different colors of light, the pixels PXL may have different surface areas (or different sizes) or different shapes by colors.

The driver may provide a signal and a power voltage to each pixel PXL through the line component to control the operation of the pixel PXL.

Referring to FIG. 4, the display panel DP may include a substrate SUB, a pixel circuit layer PCL, a display element layer DPL, and a light conversion pattern layer LCPL.

The pixel circuit layer PCL may be provided on the substrate SUB, and include multiple transistors and signal lines connected to the transistors.

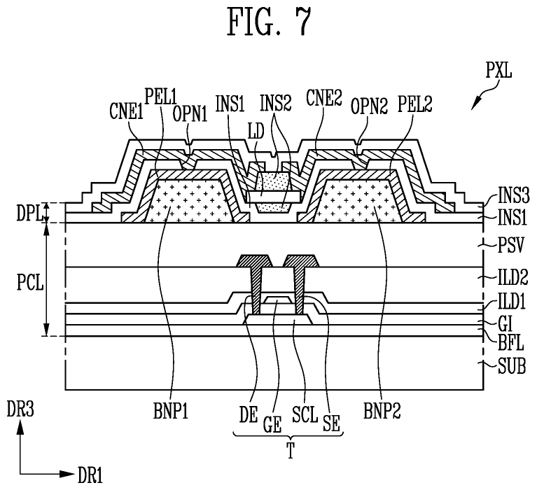

The display element layer DPL may be disposed on the pixel circuit layer PCL. The display element layer DPL may include a light emitting element configured to emit light. The light emitting element may be, e.g., an organic light emitting diode, but the disclosure is not limited thereto. In an embodiment, the light emitting element may be an inorganic light emitting element including inorganic light emitting material, or a light emitting element that emits light after changing the wavelength of the light using quantum dots. Detailed descriptions of the structures of the pixel circuit layer PCL and the display element layer DPL will be made with reference to FIG. 7.

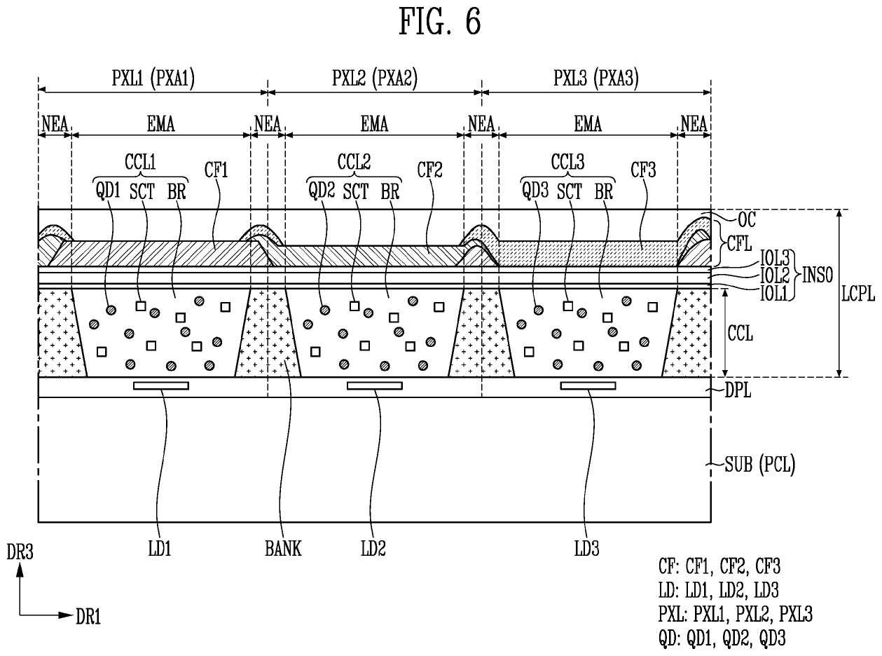

The light conversion pattern layer LCPL may be disposed on the display element layer DPL. The light conversion pattern layer LCPL may include a quantum dot to convert the wavelength (or the color) of light emitted from the display element layer DPL, and may include a color filter to allow a specific wavelength (or a specific color) of light to selectively pass therethrough. The light conversion pattern layer LCPL may be formed, through a continuous process, on a base surface provided by the display element layer DPL. Detailed description of the structure of the light conversion pattern layer LCPL will be made below with reference to FIG. 6.

An overcoat layer OC may form on an uppermost layer of the display panel DP. The overcoat layer OC may be an encapsulation layer having a multi-layer structure. The overcoat layer OC may include an inorganic layer and/or an organic layer. For example, the overcoat layer OC may have a structure formed by successively stacking an inorganic layer, an organic layer, and an inorganic layer. The overcoat layer OC may prevent external air or water from permeating to the display element layer DPL or the pixel circuit layer PCL.

A touch sensor (not illustrated) may be disposed between the display panel DP and the optical layer ARU. The touch sensor may be directly disposed on a surface from which an image is displayed, and be configured to receive a touch input of the user.

The circuit board FB may be connected to an end (or a surface adjacent to a side, e.g., the pad component PDA) of the display panel DP and provide a driving signal and a voltage to the display panel DP. For example, the driving signal may be a signal to display an image on the display panel DP, and the voltage may be a driving voltage needed to drive the display panel DP. The circuit board FB may be provided as a flexible printed circuit board (FPCB). As illustrated in FIG. 2, the circuit board FB may be folded along a side surface of the display panel DP and disposed on a rear surface of the display panel DP. The circuit board FB may process various signals inputted from a printed circuit board PB and output the processed signals to the display panel DP. The circuit board FB may be attached to each of the display panel DP and the printed circuit board PB. For example, a first end (or a surface adjacent to a first side) of the circuit board FB may be bonded to the display panel DP by a conductive adhesive ACF. A second end (or a surface adjacent to a second side) of the circuit board FB that faces the first end may be bonded to the printed circuit board PB by another conductive adhesive (not shown). Each of the conductive adhesive ACF and the other conductive adhesive may include an anisotropic conductive film.

The conductive adhesive ACF may include conductive particles PI formed in an adhesive film PF having adhesiveness. The conductive particles PI may electrically connect the first pads PD1 of the display panel DP with second pads PD2 of the circuit board FB. Hence, signals of voltages of the driving power supply that are transmitted to the second pads PD2 through the driver DIC mounted on the circuit board FB may be transmitted to the first pads PD1 of the display panel DP through the conductive adhesive ACF.

The first pads PD1 may be provided with an interval on a pad area located in the non-display area NDA of the substrate SUB. The second pads PD2 may be provided with an interval on a base layer BSL of the circuit board FB.

The driver DIC may be located on the circuit board FB. The driver DIC may be an integrated circuit (IC). The driver DIC may receive driving signals outputted from the printed circuit board PB, and output signals, driving power voltages (or driving power), and the like to each of the pixels PXL, based on the received driving signals. The signals and the driving power voltages may be transmitted to the first pads PD1 on the display panel DP through the second pads PD2 on the circuit board FB.

In the foregoing embodiment, the driver DIC has been described as being disposed on the circuit board FB, but the disclosure is not limited thereto. In an embodiment, the driver DIC may be disposed (or mounted) on the substrate SUB of the display panel DP.

The printed circuit board PB may generate driving signals and power supply signals needed to drive the display panel DP, and provide the driving signals and the power supply signals to the display panel DP. The printed circuit board PB may include a pad (not illustrated). The pad may be electrically connected to the pads of the circuit board FB. As a result, the driving signals and the power supply signals may be transmitted from the printed circuit board PB to the driver DIC through the circuit board FB.

The printed circuit board PB may be configured in various forms. For example, the printed circuit board PB may be configured by placing at least one copper foil layer on a surface or each of opposite surfaces of a base substrate made of epoxy resin or the like, or may be configured by placing at least one copper foil layer on a surface or each of opposite surfaces of a plastic film having flexibility. The printed circuit board PB may have a multi-layer structure in which a copper foil layer is formed on the base substrate.

The optical layer ARU may be located on the display panel DP and the circuit board FB. The optical layer ARU may reduce reflection of external light. The optical layer ARU may be an antireflection layer (or an antireflection film) including a polarizing film and/or a phase delay film. The number of phase delay films and a phase delay length (λ/4 or λ/2) of each phase delay film may be determined depending on the operation principle of the optical layer ARU. In an embodiment, the optical layer ARU may include color filters.

The base casing BC may provide a rear surface of the display device DD and define an internal space of the display device DD. The base casing BC may include a material having relatively high stiffness. For example, the base casing BC may include multiple frames and/or plates formed of glass, plastic, or metal. The base casing BC may reliably protect the components of the display device DD disposed in the internal space from external shocks. Although the base casing BC has been described as having relatively high stiffness, the disclosure is not limited thereto, and the base casing BC may include flexible material. Although not illustrated, the display device DD in accordance with an embodiment of the disclosure may have foldable or bendable characteristics. As a result, the components included in the display device DD may also have flexible characteristics.

In an embodiment, the display device DD (or the display module DM) may further include a protective layer CRD (or a protective unit, or a protective pattern) which covers a side surface of each of the circuit board FB and the display panel DP.

As illustrated in FIG. 5, the protective layer CRD may cover a side surface of each of the circuit board FB and the display panel DP and prevent the pads of each of the circuit board FB and the display panel DP from corroding. The protective layer CRD may cover a side surface of each of the circuit board FB and the display panel DP and prevent external water or moisture, or the like from being drawn into the pixels PXL. The protective layer CRD may more reliably couple the circuit board FB and the display panel DP that are bonded to each other.

In an embodiment, the protective layer CRD may be made of a resin. For example, the protective layer CRD may be made of a thermosetting resin including a thermal polymerization initiator, which initiates a thermal curing reaction. In an embodiment, the protective layer CRD may be made of a photocurable resin including a light polymerization initiator, which is cross-liked and cured by light such as ultraviolet rays, or infrared rays.

FIG. 6 is a schematic cross-sectional view illustrating an embodiment of the display panel DP of FIG. 4. FIG. 6 schematically illustrates the display panel DP in the display area DA.

Referring to FIGS. 3, 4, and 6, a first pixel PXL1, a second pixel PXL2, and a third pixel PXL3 may be disposed on the substrate SUB. The first, second, and third pixels PXL1, PXL2, and PXL3 may form a unit pixel, but the disclosure is not limited thereto.

In an embodiment, the first, second, and third pixels PXL1, PXL2, and PXL3 may emit light of different colors. For example, the first pixel PXL1 may be a red pixel configured to emit red light, the second pixel PXL2 may be a green pixel configured to emit green light, and the third pixel PXL3 may be a blue pixel configured to emit blue light. However, the colors, types and/or number of pixels forming the unit pixel are not particularly limited. For example, the color of light which is emitted from each pixel may be changed in various ways. In an embodiment, the first, second, and third pixels PXL1, PXL2, and PXL3 may emit light of the same color. For example, each of the first to third pixels PXL1, PXL2, and PXL3 may be a blue pixel configured to emit blue light.

In an embodiment of the disclosure, unless otherwise explained, “components are provided and/or formed on the same layer” may mean that the components are formed through the same process, and “components are provided and/or formed on different layers” may mean that the components are formed through different processes.

The pixel circuit layer PCL and the display element layer DPL may be disposed on the substrate SUB. Although for convenience of explanation the pixel circuit layer PCL is illustrated along with the substrate SUB, the pixel circuit layer PCL may be disposed between the substrate SUB and the display element layer DPL, as described in FIG. 4.

The display element layer DPL may include a light emitting element LD provided in each emission area EMA. For example, a first light emitting element LD1 may be provided in the first pixel area PXA1, a second light emitting element LD2 may be provided in the second pixel area PXA2, and a third light emitting element LD3 may be provided in the third pixel area PXA3.

The light emitting element LD may be formed of an organic light emitting diode, an inorganic light emitting diode, or a quantum dot light emitting diode. In an embodiment, the light emitting element LD may be formed of a light emitting diode which is made of material having an inorganic crystal structure and has a small size ranging from the nanometer scale to the micrometer scale. The light emitting element LD may be connected in parallel and/or series to light emitting elements LD disposed adjacent thereto in each pixel PXL, but the disclosure is not limited thereto. The light emitting element LD may form a light source of each pixel PXL. In other words, each of the pixels PXL may include at least one light emitting element LD which is driven by a signal (e.g., a scan signal and a data signal) and/or a power supply (e.g., a first driving power supply and a second driving power supply).

The light conversion pattern layer LCPL may include a color conversion layer CCL, an insulating layer INSO (or a refractive index conversion layer), a color filter layer CFL (or a color filter CF), and an overcoat layer OC.

The color conversion layer CCL may include a bank BANK, and first, second, and third color conversion patterns CCL1, CCL2 and CCL3 (or first, second, and third color conversion layers).

The bank BNK may be disposed on the display element layer DPL.

The bank BNK may be located in the non-emission areas NEA of the first to third pixels PXL1, PXL2, and PXL3. The bank BANK may be formed between the first to third pixels PXL1, PXL2, and PXL3 in such a way that the bank BANK encloses the respective emission areas EMA of the first to third pixels PXL2, PXL2, and PXL3, thus defining the respective emission areas EMA. The bank BANK may function as a dam structure which prevents a solution for forming the first, second, or third color conversion pattern CCL1, CCL2, or CCL3 in each emission area EMA from being drawn into adjacent emission area EMA, or controls the amount of solution such that a certain amount of solution is supplied to each emission area EMA.

Openings through which the display element layer DPL is exposed may be formed in the bank BNK at respective positions corresponding to the emission areas EMA.

The first, second, and third color conversion patterns CCL1, CCL2, and CCL3 may be disposed in the respective openings of the bank BNK.

Each of the first, second, and third color conversion patterns CCL1, CCL2, and CCL3 may include base resin BR, color conversion particles QD, and light scattering particles SCT.

The base resin BR may have a relatively high light transmissivity, and have excellent scattering characteristics for the color conversion particles QD. For example, the base resin BR may include an organic material such as an epoxy resin, an acrylic resin, a cardo resin, or an imide resin.

The color conversion particles QD may convert the color of light emitted from the light emitting element LD disposed in the corresponding pixel to a specific color of light. For example, in the case where the first pixel PXL1 is a red pixel, the first color conversion layer CCL1 may include first color conversion particles QD1 formed of red quantum dots which convert light emitted from the first light emitting element LD1 to red light. In the case where the second pixel PXL2 is a green pixel, the second color conversion layer CCL2 may include second color conversion particles QD2 formed of green quantum dots which convert light emitted from the second light emitting element LD2 to green light. In the case where the third pixel PXL3 is a blue pixel, the third color conversion layer CCL3 may include third color conversion particles QD3 formed of blue quantum dots which convert light emitted from the third light emitting element LD3 to blue light. Unlike the foregoing, in the case where the third light emitting element LD3 emits blue light, the third color conversion layer CCL3 may not include the third color conversion particles QD3.

The light scattering particles SCT may have a refractive index different from that of the base resin BR, and form an optical interface with the base resin BR. The light scattering particles SCT may be metal oxide particles or organic particles. In an embodiment, the light scattering particles SCT may be omitted.

The insulating layer INSO may be disposed on the color conversion layer CCL. The insulating layer INSO may be disposed on an entire surface of the substrate to cover the color conversion layer CCL (i.e., the bank BANK and the first, second, and third color conversion patterns CCL1, CCL2, and CCL3).

The insulating layer INSO may include at least three insulating layers, and use a difference in refractive index (or total reflection attributable to the difference in refractive index) between the three insulating layers to recycle light (e.g., light traveling in a diagonal direction) emitted from the color conversion layer CCL. For example, light that is total-reflected by the insulating layer INSO may be re-reflected in the third direction DR3 by the display element layer DPL (or an electrode that is included in the display element layer DPL and has a specific reflectivity), or may be scattered in the third direction DR3 by the color conversion layer CCL (e.g., the light scattering particles SCT). Therefore, the efficiency (or the external quantum efficiency or light output efficiency) of light that is ultimately emitted from the pixel PXL after passing through the insulating layer INSO, or the emission luminance of the pixel PXL may be enhanced.

In embodiments, the insulating layer INSO may include a first inorganic layer IOL1 (or a first dense film), a second inorganic layer IOL2 (or a low refractive layer), and a third inorganic layer 1OL3 (or a second dense film) which are successively stacked on the color conversion layer CCL.

The first inorganic layer IOL1 may be disposed on the color conversion layer CCL to prevent water (or a solution to be used during a subsequent process) from permeating the color conversion layer CCL disposed thereunder. The second inorganic layer IOL2 may be disposed on the first inorganic layer IOL1, and may have a different refractive index from the first inorganic layer IOL1 to totally reflect light (e.g., light traveling in a diagonal direction) emitted from the color conversion layer CCL. The third inorganic layer 10L3 may be disposed on the second inorganic layer 10L2, and enhance adhesive force between the second inorganic layer 10L2 and the color filter layer CFL that is disposed thereover.

The color filter layer CFL may be disposed on the insulating layer INS0.

The color filter layer CFL may include color filter material that allows a specific color of light converted by the color conversion layer CCL to selectively pass therethrough. The color filter layer CFL may include a red color filter, a green color filter, and a blue color filter. For example, in the case where the first pixel PXL1 is a red pixel, a first color filter CF1 configured to allow red light to pass therethrough may be disposed in the first pixel PXL1. In the case where the second pixel PXL2 is a green pixel, a second color filter CF2 configured to allow green light to pass therethrough may be disposed in the second pixel PXL2. In the case where the third pixel PXL3 is a blue pixel, a third color filter CF3 configured to allow blue light to pass therethrough may be disposed in the third pixel PXL3.

The overcoat layer OC may be disposed on the color filter layer CFL. The overcoat layer OC may be disposed on an entire surface of the substrate SUB to cover components disposed thereunder, and encapsulate the display area DA of the display panel DP (refer to FIG. 2).

FIG. 7 is a schematic cross-sectional view illustrating embodiments of the pixel circuit layer PCL and the display element layer DPL that are included in the display panel DP of FIG. 6. Although FIG. 7 schematically illustrates a pixel PXL, e.g., illustrating a single electrode and a single insulating layer, the disclosure is not limited thereto.

In an embodiment of the disclosure, the term “connection” between two components may embrace electrical connection and physical connection.

Referring to FIGS. 3, 4, 6, and 7, each pixel PXL may include a pixel circuit layer PCL and a display element layer DPL which are disposed on the substrate SUB.

The pixel circuit layer PCL will be first described, and the display element layer DPL will be described.

The pixel circuit layer PCL may include a buffer layer BFL, a transistor T, and a passivation layer PSV.

The buffer layer BFL may be provided and/or formed on the substrate SUB and prevent impurities from diffusing into the transistor T. The buffer layer BFL may be an inorganic layer including an inorganic material. The buffer layer BFL may include at least one of silicon nitride (SiNₓ), silicon oxide (SiOₓ), silicon oxynitride (SiOₓN_{y}), and a metal oxide such as aluminum oxide (AlOₓ). The buffer layer BFL may be provided in a single-layer structure or a multi-layer structure having at least two or more layers. In the case where the buffer layer BFL has a multi-layer structure, the layers may be formed of the same material or different materials. The buffer layer BFL may be omitted depending on the material of the substrate SUB or processing conditions.

The transistor T may be a driving transistor configured to control driving current to be provided to the light emitting element LD. However, the disclosure is not limited to the foregoing, and the transistor T may be a switching transistor configured to transmit a signal to the driving transistor or perform other functions, rather than being a driving transistor.

The transistor T may include a semiconductor pattern SCL, a gate electrode GE, a first terminal SE, and a second terminal DE. The first terminal SE may be one of a source electrode or a drain electrode, and the second terminal DE may be another electrode. For example, in case that the first terminal SE is a source electrode, the second terminal DE may be a drain electrode.

The semiconductor pattern SCL may be provided and/or formed on the buffer layer BFL. The semiconductor pattern SCL may include a first contact area which contacts the first terminal SE, and a second contact area which contacts the second terminal DE. An area between the first contact area and the second contact area may be a channel area. The channel area may overlap the gate electrode GE of the corresponding transistor T in the third direction DR3. The semiconductor pattern SCL may be made of amorphous silicon, poly silicon, low temperature poly silicon, an oxide semiconductor, an organic semiconductor, or the like. For example, the channel area may be a semiconductor pattern undoped with impurities and be an intrinsic semiconductor. Each of the first contact area and the second contact area may be a semiconductor pattern doped with an impurity.

The gate electrode GE may be provided and/or formed on the gate insulating layer GI to correspond to the channel area of the semiconductor pattern SCL. The gate electrode GE may be provided on the gate insulating layer GI and overlap the channel area of the semiconductor pattern SCL. The gate electrode GE may have a single layer structure formed of copper (Cu), molybdenum (Mo), tungsten (W), aluminum neodymium (AlNd), titanium (Ti), aluminum (Al), silver (Ag), an alloy thereof, or a combination thereof, or may have a double layer or multilayer structure formed of molybdenum (Mo), titanium (Ti), copper (Cu), aluminum (Al), or silver (Ag) to reduce line resistance.

The gate insulating layer GI may be formed of an inorganic layer including an inorganic material. For example, the gate insulating layer GI may include at least one of silicon nitride (SiNₓ), silicon oxide (SiOₓ), silicon oxynitride (SiOₓN_{y}), and a metal oxide such as aluminum oxide (AlOₓ). However, the material of the gate insulating layer GI is not limited to the foregoing embodiments. In embodiments, various materials may be used so long as insulating properties can be provided to the gate insulating layer GI. For example, the gate insulating layer GI may be formed of an organic layer including an organic material. The gate insulating layer GI may be provided in a single-layer structure or a multi-layer structure having at least two or more layers.

The first terminal SE and the second terminal DE may be provided and/or formed on a second interlayer insulating layer ILD2 and respectively contact the first contact area and the second contact area of the semiconductor pattern SCL through contact holes successively passing through the gate insulating layer GI, and the first and second interlayer insulating layers ILD1 and ILD2. For example, the first terminal SE may contact the first contact area of the semiconductor pattern SCL, and the second terminal DE may contact the second contact area of the semiconductor pattern SCL. Each of the first and second terminals SE and DE may include the same material as that of the gate electrode GE, or include one or more materials that can be used for forming the gate electrode GE.

The first interlayer insulating layer ILD1 may include the same material as that of the gate insulating layer GI, or may include one or more materials that can be used for forming the gate insulating layer GI.

A second interlayer insulating layer ILD2 may be provided and/or formed on the first interlayer insulating layer ILD1. The second interlayer insulating layer ILD2 may be an inorganic layer including an inorganic material or an organic layer including an organic material. In an embodiment, the second interlayer insulating layer ILD2 may include the same material as that of the first interlayer insulating layer ILD1, but the disclosure is not limited thereto. The second interlayer insulating layer ILD2 may be provided in a single-layer structure or a multi-layer structure having at least two or more layers. In an embodiment, the second interlayer insulating layer ILD2 may be omitted.

Although in the foregoing embodiment, each of the first and second terminals SE and DE of the transistor T has been described as being a separate electrode electrically connected to the semiconductor pattern SCL through the contact hole that successively passes through the gate insulating layer GI and the first and second interlayer insulating layers ILD1 and ILD2, the disclosure is not limited thereto. In an embodiment, the first terminal SE of the transistor T may be a first contact area adjacent to the channel area of the semiconductor pattern SCL. The second terminal DE of the transistor T may be a second contact area adjacent to the channel area of the semiconductor pattern SCL. The second terminal DE of the transistor T may be electrically connected to the light emitting element LD of the pixel PXL through a separate connector such as a bridge electrode.

Although in the foregoing embodiment, the transistor T has been illustrated as a thin-film transistor having a top gate structure, the disclosure is not limited thereto. The structure of the transistor T may be changed in various ways. For example, the transistor T may be a thin film transistor having a bottom gate structure.

The pixel circuit layer PCL may include a storage capacitor configured to store a voltage applied between the gate electrode and the first terminal SE (or the source electrode) of the transistor T, and a driving voltage line configured to provide a driving voltage to the transistor T (or the pixel PXL), and the like.

The passivation layer PSV may be provided and/or formed on the transistor T.

The passivation layer PSV may be provided in a structure including an organic layer, an inorganic layer, or an organic layer disposed on the inorganic layer. The inorganic layer may include, for example, at least one of silicon oxide (SiOₓ), silicon nitride (SiNₓ), silicon oxynitride (SiOₓN_{y}), and a metal oxide such as aluminum oxide (AlOₓ). The organic layer may include, for example, at least one of a polyacrylates resin, an epoxy resin, a phenolic resin, a polyamide resin, a polyimide rein, an unsaturated polyesters resin, a poly-phenylen ethers resin, a poly-phenylene sulfides resin, and a benzocyclobutene resin. The display element layer DPL may be provided on the passivation layer PSV.

The display element layer DPL may include first and second bank patterns BNP1 and BNP2, first and second pixel electrodes PEL1 and PEL2, a light emitting element LD, and first and second contact electrodes CNE1 and CNE2. The display element layer DPL may include first, second, and third insulating layers INS1, INS2, and INS3.

The first and second bank patterns BNP1 and BNP2 may be located in the emission area EMA (refer to FIG. 6), and may be spaced apart from each other. The first and second bank patterns BNP1 and BNP2 may be support components which respectively support the first and second pixel electrodes PEL1 and PEL2 to change respective surface profiles (or shapes) of the first and second pixel electrodes PEL1 and PEL2 with respect to the third direction DR3, so that light emitted from the light emitting elements LD may be guided in an image display direction (e.g., in a frontal direction) of the display device. In other words, the first and second bank patterns BNP1 and BNP2 may change the respective surface profiles (or shapes) of the first and second pixel electrodes PEL1 and PEL2 with respect to the third direction DR3.

The first and second bank patterns BNP1 and BNP2 may be provided and/or formed between the passivation layer PSV and the corresponding electrode in the emission area of the corresponding pixel PXL. For example, the first bank pattern BNK1 may be provided and/or formed between the passivation layer PSV and the first pixel electrode PEL1, and the second bank pattern BNK2 may be provided and/or formed between the passivation layer PSV and the second pixel electrode PEL2.

Each of the first and second bank patterns BNP1 and BNP2 may be an inorganic layer including an inorganic material or an organic layer including an organic material. In an embodiment, each of the first and second bank patterns BNP1 and BNP2 may include an organic layer having a single-layer structure and/or an inorganic layer having a single-layer structure, but the disclosure is not limited thereto. In an embodiment, each of the first and second bank patterns BNP1 and BNP2 may be provided in the form of a multi-layer structure formed by stacking at least one organic layer and at least one inorganic layer each other. However, the material of the first and second bank patterns BNP1 and BNP2 is not limited to the foregoing embodiments. In an embodiment, the first bank pattern BNK1 may include a conductive material.

Each of the first and second bank patterns BNP1 and BNP2 may have a trapezoidal shape in a cross-sectional view which is reduced in width from a surface (e.g., an upper surface) of the passivation layer PSV upward in the third direction DR3, but the disclosure is not limited thereto. In an embodiment, each of the first and second bank patterns BNP1 to BNP2 may include a curved surface such as a semi-elliptical shape or a semi-circular shape (or a hemispherical shape) in a cross-sectional view which is reduced in width from a surface of the passivation layer PSV upward in the third direction DR3. However, the shape of the first and second bank patterns BNP1 and BNP2 is not limited to the foregoing embodiments, and may be changed in various ways within a range in which the efficiency of light emitted from each of the light emitting elements LD may be enhanced. The first and second bank patterns BNP1 and BNP2 adjacent to each other in the first direction DR1 may be disposed on the same surface on the passivation layer PSV and have the same height (or thickness) in the third direction DR3.

Although in the foregoing embodiment, there has been described that the first and second bank patterns BNP1 and BNP2 are provided and/or formed on the passivation layer PSV and the first and second bank patterns BNP1 and BNP2 and the passivation layer PSV are formed through different processes, the disclosure is not limited thereto. In an embodiment, the first and second bank patterns BNP1 and BNP2 and the passivation layer PSV may be formed through the same process. According to the embodiment, the first and second bank patterns BNP1 and BNP2 may be a portion of the passivation layer PSV.

The first and second pixel electrodes PEL1 and PEL2 may be provided and/or formed on the first and second bank patterns BNP1 and BNP2 corresponding thereto.

Each of the first and second pixel electrodes PEL1 and PEL2 may be formed of material having a reflectivity to reflect light emitted from the light emitting elements LD to travel in the image display direction of the display device. Each of the first and second pixel electrodes PEL1and PEL2 may be formed of a conductive material having a certain reflectivity. The conductive material may include an opaque metal which is advantageous for reflecting, in the image display direction of the display device, light emitted from the light emitting element LD. For example, the opaque metal may include a metal such as silver (Ag), magnesium (Mg), aluminum (Al), platinum (Pt), palladium (Pd), gold (Au), nickel (Ni), neodymium (Nd), iridium (Ir), chrome (Cr), titanium (Ti), and an alloy thereof. In an embodiment, each of the first and second pixel electrodes PEL1 and PEL2 may include a transparent conductive material. The transparent conductive material may include transparent conductive oxides such as indium tin oxide (ITO), indium zinc oxide (IZO), zinc oxide (ZnOₓ), indium gallium zinc oxide (IGZO), and indium tin zinc oxide (ITZO), or a conductive polymer such as poly(3,4-ethylenedioxythiophene) (PEDOT).

In the case where each of the first and second pixel electrodes PEL1 and PEL2 includes a transparent conductive material, a separate conductive layer formed of an opaque metal for reflecting light emitted from the light emitting element LD in the image display direction of the display device may be added. However, the material of each of the first and second pixel electrodes PEL1 and PEL2 is not limited to the foregoing materials.

Each of the first and second pixel electrodes PEL1 and PEL2 may be provided and/or formed in a single-layer structure, but the disclosure is not limited thereto. In an embodiment, each of the first and second pixel electrodes PEL1 and PEL2 may be provided and/or formed in a multi-layer structure formed by stacking at least two materials among metals, alloys, conductive oxides, and conductive polymers each other. Each of the first and second pixel electrodes PEL1 and PEL2 may have a multi-layer structure including at least two layers to minimize distortion resulting from a signal delay in case that signals (or voltages) are transmitted to opposite ends of each of the light emitting elements LD. For example, each of the first and second pixel electrodes PEL1 and PEL2 may be formed of a multi-layer structure formed by stacking layers in a sequence of indium tin oxide (ITO)/silver(Ag)/indium tin oxide (ITO).

In an embodiment, the first pixel electrode PEL1 may be electrically connected to the transistor T through a first contact hole passing through the passivation layer PSV. The second pixel electrode PEL2 may be electrically connected to the driving voltage line of the pixel circuit layer PCL through a second contact hole passing through the passivation layer PSV.

The first pixel electrode PEL1 and the second pixel electrode PEL2 may respectively receive certain alignment signals (or an alignment voltages) from corresponding components of the pixel circuit layer PCL, and may be used as alignment electrodes (or alignment lines) for aligning the light emitting elements LD. For example, the first pixel electrode PEL1 may receive a first alignment signal (or a first alignment voltage) from a component of the pixel circuit layer PCL and be used as a first alignment electrode (or a first alignment line). The second pixel electrode PEL2 may receive a second alignment signal (or a second alignment voltage) from another component of the pixel circuit layer PCL and be used as a second alignment electrode (or a second alignment line).

After the light emitting element LD is aligned in the pixel PXL, a portion of the first pixel electrode PEL that is located between adjacent pixels PXL may be removed to individually (or independently) drive each pixel PXL.

After the light emitting elements LD are aligned, the first pixel electrode PEL1 and the second pixel electrode PEL2 may be used as driving electrodes for driving the light emitting elements LD, but the disclosure is not limited thereto.

The light emitting element LD may be formed of a light emitting diode which is made of a material having an inorganic crystal structure and has a subminiature size, e.g., ranging from the nanometer scale to the micrometer scale. For example, the light emitting element LD may include a first semiconductor layer, a second semiconductor layer, an active layer, and an insulating layer. The first semiconductor layer may include a semiconductor layer having a certain type. The second semiconductor layer may include a semiconductor layer having a type different from that of the first semiconductor layer. For example, the first semiconductor layer may be an N-type semiconductor layer, and the second semiconductor layer may be a P-type semiconductor layer. Each of the first semiconductor layer and the second semiconductor layer may include at least one semiconductor material such as InAIGaN, GaN, AIGaN, InGaN, AIN, and InN. The active layer may be located between the first semiconductor layer and the second semiconductor layer, and may have a single or multi-quantum well structure. In case that an electric field having a certain voltage or more is applied between the opposite ends of the light emitting element LD, light may be emitted by coupling of electron-hole pairs in the active layer.

At least two to several tens of light emitting elements LD may be aligned and/or provided in the emission area EMA, but the number of light emitting elements LD aligned and/or provided in the emission area EMA is not limited thereto. The number of light emitting elements LD aligned and/or provided in the emission area EMA may be changed in various ways.

Each of the light emitting elements LD may emit light of a color and/or white light. In an embodiment, each of the light emitting elements LD may emit blue light of a short-wavelength band, but the disclosure is not limited thereto.

The first insulating layer INS1 may be provided and/or formed on the first and second pixel electrodes PEL1 and PEL2.

The first insulating layer INS1 may be formed of an inorganic layer made of an inorganic material, or an organic layer made of an organic material. The first insulating layer INS1 may be formed of an inorganic layer which is advantageous for protecting the light emitting element LD and/or the pixel circuit layer PCL of the pixel PXL. For example, the first insulating layer INS1 may include at least one of silicon nitride (SiNₓ), silicon oxide (SiOₓ), silicon oxynitride (SiOₓN_{y}), and a metal oxide such as aluminum oxide (AlOₓ), but the disclosure is not limited thereto. In an embodiment, the first insulating layer INS1 may be formed of an organic insulating layer that is advantageous for planarizing support surfaces of the light emitting elements LD.

The first insulating layer INS1 may include a first opening OPN1 through which an area of the first pixel electrode PEL1 is exposed, and a second opening OPN2 through which an area of the second pixel electrode PEL2 is exposed. The first insulating layer INS1 may cover an entire area of each of the first and second pixel electrodes PEL1 and PEL2 other than the areas thereof (i.e., an area corresponding to the first or second opening OPN1 or OPN2). The light emitting elements LD may be disposed (or aligned) on the first insulating layer INS1 between the first pixel electrode PEL1 and the second pixel electrode PEL2.

The second insulating layer INS2 (or a second insulating pattern) may be provided and/or formed on the light emitting element LD. The second insulating layer INS2 may be provided and/or formed on the light emitting element LD and partially cover the outer circumferential surface (or the outer surface) of each of the light emitting element LD. The second insulating layer INS2 may prevent the active layer of the light emitting element LD from contacting external conductive material. The second insulating layer INS2 may cover only a portion of the outer circumferential surface (or the outer surface) of the light emitting element LD so that the opposite ends of the light emitting element LD may be exposed to the outside. The second insulating layer INS2 may be formed as an independent insulating pattern in the pixel PXL, but the disclosure is not limited thereto.

The second insulating layer INS2 may have a single-layer structure or a multi-layer structure, and include an inorganic layer including at least one inorganic material or an organic layer including at least one organic material. The second insulating layer INS2 may be formed of an inorganic layer including an inorganic material and/or an organic layer including an organic material, depending on design conditions, and the like of the display device to which the light emitting elements LD may be applied. After the alignment of the light emitting element LD is completed, the second insulating layer INS2 may be formed on the light emitting elements LD so that the light emitting elements LD may be prevented from being removed from the aligned position.

The first contact electrode CNE1 may be provided on the first pixel electrode PEL1, and may contact or connected to the first pixel electrode PEL1 through the first opening OPN1 of the first insulating layer INS1. In an embodiment, in the case where a capping layer (not illustrated) is disposed on the first pixel electrode PEL1, the first contact electrode CNE1 may be disposed on the capping layer and be connected to the first pixel electrode PEL1 through the capping layer (or an opening in the capping layer). The capping layer may protect the first pixel electrode PEL1 from a defect or the like, which may occur during a process of fabricating the display device, and increase adhesive force between the first pixel electrode PEL1 and the pixel circuit layer PCL disposed therebelow. The capping layer may include a transparent conductive material (or substance) such as indium zinc oxide (IZO).

Although the first contact electrode CNE1 has been described as being connected to the first pixel electrode PEL1, the disclosure is not limited thereto. For example, the first contact electrode CNE1 may be directly connected to a component (e.g., the transistor T) of the pixel circuit layer PCL rather than being connected through the first pixel electrode PEL1.

The first contact electrode CNE1 may be provided and/or formed on a first end of the light emitting element LD and connected to the first end of the light emitting element LD. Therefore, the first pixel electrode PEL1 and the first end of the light emitting element LD may be electrically connected to each other through the first contact electrode CNE1.

In a manner similar to the first contact electrode CNE1, the second contact electrode CNE2 may be provided on the second pixel electrode PEL2, and may contact or connected to the second pixel electrode PEL2 through the second opening OPN2 of the first insulating layer INS1. In an embodiment, in the case where a capping layer is disposed on the second pixel electrode PEL2, the second contact electrode CNE2 may be disposed on the capping layer and be connected to the second pixel electrode PEL2 through an opening in the capping layer. The second contact electrode CNE2 may be provided and/or formed on a second end of the light emitting element LD and connected to the second end of the light emitting element LD. Therefore, the second pixel electrode PEL2 and the second end of the light emitting element LD may be electrically connected to each other through the second contact electrode CNE2.

Although the second contact electrode CNE2 has been described as being connected to the second pixel electrode PEL2, the disclosure is not limited thereto. For example, the second contact electrode CNE2 may not be connected to the second pixel electrode PEL2.

The first and second contact electrodes CNE1 and CNE2 may be formed of a transparent conductive material to reflect light emitted from the light emitting element LD by the first and second pixel electrodes PEL1 and PEL2 to travel in the image display direction of the display device without loss. For example, the first and second contact electrodes CNE1 and CNE2 may include at least one of various transparent conductive materials (or substances) including indium tin oxide (ITO), indium zinc oxide (IZO), zinc oxide (ZnOₓ), indium gallium zinc oxide (IGZO), and indium tin zinc oxide (ITZO), and be substantially transparent or translucent to satisfy a transmittance. The material of the first and second contact electrodes CNE1 and CNE2 is not limited to the above-mentioned materials. In an embodiment, the first and second contact electrodes CNE1 and CNE2 may be formed of an opaque conductive material (or substance). Each of the first and second contact electrodes CNE1 and CNE2 may be formed of a single layer or multiple layers.

The shape of each of the first and second contact electrodes CNE1 and CNE2 is not limited to a specific shape, and may be changed in various ways within a range capable of being reliably electrically connected with the light emitting element LD. The shape of each of the first and second contact electrodes CNE1 and CNE2 may be changed in various ways, taking into account a connection relationship with electrodes disposed therebelow.

The first and second contact electrodes CNE1 and CNE2 may be spaced apart from each other in the first direction DR1. For example, the first connection electrode CNE1 and the second connection electrode CNE2 may be disposed on the second insulating layer INS2 at positions spaced apart from each other by a certain distance. The first contact electrode CNE1 and the second contact electrode CNE2 may be provided on an identical layer and formed through an identical process. However, the disclosure is not limited thereto. In an embodiment, the first and second contact electrodes CNE1 and CNE2 may be provided on different layers and formed through different processes.

The third insulating layer INS3 may be provided and/or formed on the first and second contact electrodes CNE1 and CNE2. The third insulating layer INS3 may be an inorganic layer including an inorganic material or an organic layer including an organic material. For example, the third insulating layer INS3 may have a structure formed by alternately stacking at least one inorganic layer and at least one organic layer each other. The third insulating layer INS3 may cover the entirety of the display element layer DPL and prevent water or moisture from being drawn into the display element layer DPL including the light emitting elements LD from the outside. In an embodiment, the third insulating layer INS3 may be omitted.

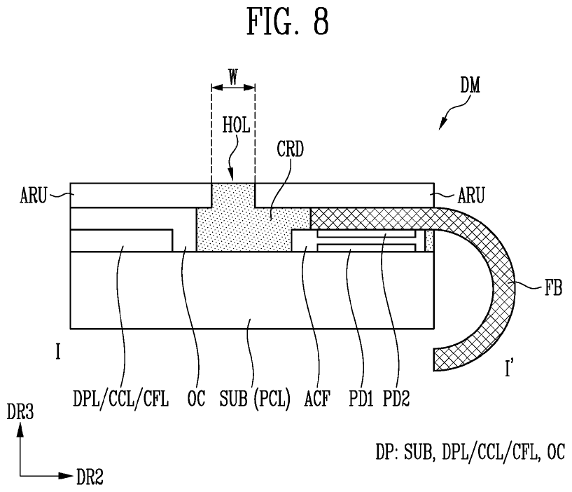

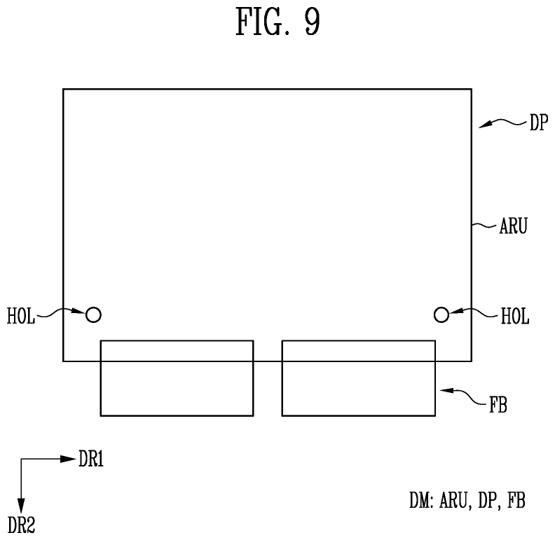

FIG. 8 is a schematic cross-sectional view illustrating an embodiment of a display module DM taken along line I-I′ of FIG. 2. FIG. 9 is a plan view illustrating the display module DM of FIG. 8.

Referring to FIGS. 1 to 9, the display module DM may include a display panel DP, a circuit board FB, and an optical layer ARU.

The display panel DP may include a substrate SUB, a display element layer DPL (and a pixel circuit layer PCL, a color conversion layer CCL, and a color filter layer CFL) including pixels PXL (refer to FIGS. 3 and 7) provided on the substrate SUB, and an overcoat layer OC which covers the display element layer DPL. The display panel DP may include first pads PD1 located on a surface of the substrate SUB.

The overcoat layer OC may be a planarization layer for mitigating a step difference caused by components included in the display panel DP disposed thereunder. The overcoat layer OC may be a protective component which covers the display panel DP and protects the pixel PXL. To this end, the overcoat layer OC may be formed of an organic layer including an organic material. The organic layer may include, for example, at least one of a polyacrylates resin, an epoxy resin, a phenolic resin, a polyamides resin, a polyimide rein, an unsaturated polyesters resin, a poly-phenylen ethers resin, a poly-phenylene sulfides resin, and a benzocyclobutene resin. However, the material of the overcoat layer OC is not limited to that of the above-mentioned materials.

An area of the display panel DP where the display element layer DPL (and the overcoat layer OC) is located may correspond to the display area of the display panel DP (i.e., the display area DA where the pixel PX of FIG. 2 is provided). Another area of the display panel DP may correspond to the non-display area NDA (refer to FIG. 2) of the display panel DP.

The circuit board FB may be disposed on a side of the display panel DP such that a surface of the circuit board FB on which the second pads PD2 are located face the first pads PD1. The circuit board FB may be bonded to the non-display area of the display panel DP. The second pads PD2 of the circuit board FB may be electrically connected to the first pads PD1 of the display panel DP through a conductive adhesive ACF. The circuit board FB may be electrically connected to the pixel PX (refer to FIG. 2) in the display panel DP. The circuit board FB may be folded along a side surface of the display module DM and disposed on the rear surface of the display module DM. The circuit board FB may be electrically connected to the printed circuit board PB (refer to FIG. 3).

The optical layer ARU may be provided on the display panel DP and the circuit board FB. The optical layer ARU may be an antireflection layer for preventing external light from being visible to a user. The optical layer ARU may cover the display panel DP and the circuit board FB.

The optical layer ARU may contact the overcoat layer OC, and may also contact the circuit board FB. In case that the optical layer ARU includes an adhesive material (e.g., pressure sensitive adhesive (PSA)) on a rear surface thereof, the optical layer ARU may be coupled or attached to the overcoat layer OC and the circuit board FB.

In an embodiment, an end (or an edge) of the optical layer ARU may be aligned with an end (or an edge) of the display panel DP. The circuit board FB may be folded or bent on the end of the display panel DP. Hence, in the case where the end of the optical layer ARU is aligned with the end of the display panel DP, the optical layer ARU may be stably attached to the circuit board FB and thus prevented from peeling off from the circuit board FB. However, the disclosure is not limited thereto. The optical layer ARU may protrude over the display panel DP (and the circuit board FB) outward (e.g., in the second direction DR2). Because an uppermost portion of the display module DM is formed of only the optical layer ARU, the display module DM may have a highly planarized surface (i.e., an overall planarized surface on the overcoat layer OC and the circuit board FB).

In an embodiment, at least one hole HOL (or a through hole, an opening, or a slit) through which a component provided under the optical layer ARU is exposed may be formed in the optical layer ARU. For example, as illustrated in FIG. 9, multiple holes HOL may be formed in the optical layer ARU. In a plan view, the hole HOL may be located adjacent to an edge of the display panel DP, but the disclosure is not limited thereto.

In an embodiment, a diameter W of the hole HOL may be equal to or less than approximately 1 mm. The reason for this is because the hole HOL may be visible to the user if the diameter of the hole HOL is greater than approximately 1 mm. However, the diameter of the hole HOL is not limited thereto.

In an embodiment, the display module DM may further include a protective layer CRD (or a cover layer, or a protective component).

As illustrated in FIG. 8, the protective layer CRD may be disposed between the optical layer ARU and the substrate SUB in the third direction DR3, and may be disposed between the overcoat layer OC and the circuit board FB (or a bonding portion). The bonding portion may be a portion where the second pads PD2 of the circuit board FB and the first pads PD1 of the display panel DP are coupled to each other by the conductive adhesive ACF. The protective layer CRD may be partially located on the bonding portion of the display panel DP.

The protective layer CRD may be charged into a space between the circuit board FB and the display panel DP and cover the bonding portion between the circuit board FB and the display panel DP. The protective layer CRD may protect the bonding portion and prevent external water, moisture, or the like from flowing into the bonding portion and permeating to the display panel DP. The protective layer CRD may support a portion of the optical layer ARU.

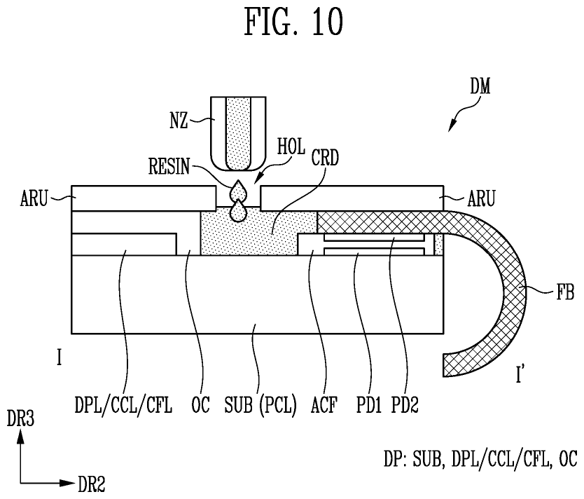

In an embodiment, the protective layer CRD may be charged through the hole HOL of the optical layer ARU. Although it will be described below with reference to FIG. 10, the protective layer CRD may be supplied and formed through the hole HOL of the optical layer ARU. During a process of forming the protective layer CRD, a portion of the protective layer CRD may be located in the hole HOL of the optical layer ARU. A protrusion corresponding to the hole HOL may be formed on an upper surface of the protective layer CRD. In a plan view, the protrusion of the protective layer CRD may have an island shape corresponding to the hole HOL. Although the protrusion of the protective layer CRD may protrude over the upper surface of the optical layer ARU in the third direction DR3 during the process of forming the protective layer CRD, a portion of the protective layer CRD that protrudes over the upper surface of the optical layer ARU may be removed by grinding, cutting, or the like. An upper surface of the protrusion of the protective layer CRD may be coplanar with the upper surface of the optical layer ARU.

In an embodiment, the protective layer CRD may include a light blocking material so that components provided under the protective layer CRD may be prevented from being visible. For example, the protective layer CRD may include a thermosetting resin including a light blocking material. In an embodiment, the protective layer CRD may include a photocurable resin including a light blocking material. For example, the protective layer CRD may include a resin based on epoxy, aryl, urethane, or the like, including black particles.

As described above, the optical layer ARU may include at least one hole HOL formed in the non-display area. The protective layer CRD may be charged into or formed in the space between the optical layer ARU and the display panel DP through the hole HOL. The protective layer CRD may at least partially cover the bonding portion between the circuit board FB and the display panel DP, thus preventing external water or moisture from being drawn into the bonding portion.

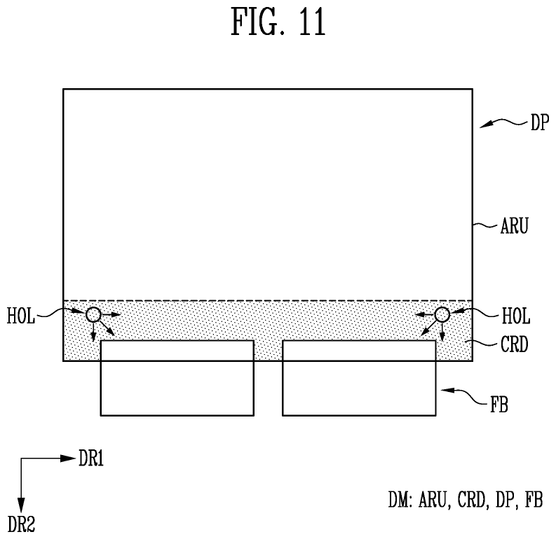

FIGS. 10 and 11 are views for describing a method of fabricating the display module DM of FIG. 8.

Referring to FIGS. 8 to 11, the optical layer ARU may be attached to the display panel DP to cover the circuit board FB.

After the optical layer ARU is attached to the display panel DP, a printing device may be located at a position corresponding to the hole HOL of the optical layer ARU, as illustrated in FIG. 10. The printing device may include a nozzle NZ. The printing device may store a resin solution RESIN in a liquid form, and supply the resin solution RESIN through the nozzle NZ. The resin solution RESIN may have a viscosity (centipoises) ranging from approximately 10 cps to approximately 100 cps, but the disclosure is not limited thereto.

The printing device may supply the resin solution RESIN to the hole HOL of the optical layer ARU through the nozzle NZ. The resin solution RESIN supplied through the hole HOL of the optical layer ARU may be charged into the space between the optical layer ARU and the substrate SUB and the space between the overcoat layer OC and the circuit board FB (or the space between the optical layer ARU, the display panel DP, and the circuit board FB). As illustrated in FIG. 11, the resin solution RESIN supplied through the hole HOL of the optical layer ARU may be filled in the first direction DR1 and the second direction DR2 and charged into or applied to the space between the overcoat layer OC and the circuit board FB.

A separate compressor may be used to pressurize the resin solution RESIN so that the space between the optical layer ARU and the substrate SUB and the space between the overcoat OC and the circuit board FB can be filled with the resin solution RESIN. In an embodiment, the amount of the supplied resin solution RESIN may be adjusted or optimized to prevent the resin solution RESIN from overflowing from an edge of the display panel DP of FIG. 11. Although it will be described below, a dam formed along a portion of the edge of the display panel DP may be used to prevent the resin solution RESIN from overflowing.

Depending on the amount of the supplied resin solution RESIN, the resin solution RESIN may be charged into at least a portion of the space between the optical layer ARU and the substrate SUB. For example, the resin solution RESIN may be charged into the entirety of the space between the optical layer ARU and the substrate SUB or may be charged into only a portion of the space between the optical layer ARU and the substrate SUB.

Thereafter, a light source device may be used to irradiate light such as ultraviolet rays or infrared rays to the resin solution RESIN (i.e., the resin solution RESIN charged into the space between the optical layer ARU and the substrate SUB). As a result, the resin solution RESIN, which is a photocurable resin, may be cured, thus forming the protective layer CRD. The optical layer ARU, the substrate SUB (or the display panel DP), and the circuit board FB may be bonded to each other by the protective layer CRD.

Although there has been described that the light source device is used, the disclosure is not limited thereto. For example, in the case where the resin solution RESIN is a thermosetting resin, a heating device in lieu of the light source device may be used to heat and pressurize the resin solution RESIN.

In an embodiment, in the case where the protective layer CRD protrudes out of the hole HOL of the optical layer ARU or includes a protrusion (e.g., a portion protruding over the optical layer ARU in the third direction DR3), the protrusion may be removed by polishing, cutting, or the like. Accordingly, the display module DM of FIG. 8 may be fabricated.

As described above, the resin solution RESIN may be charged, through the hole HOL of the optical layer ARU, into the space between the optical layer ARU and the substrate SUB and the space between the overcoat layer OC and the circuit board FB (or the space between the optical layer ARU, the display panel DP, and the circuit board FB), and cured to form the protective layer CRD. After the optical layer ARU has been disposed to cover the display panel DP and the circuit board FB, the protective layer CRD may be formed. The protective layer CRD may support the optical layer ARU.

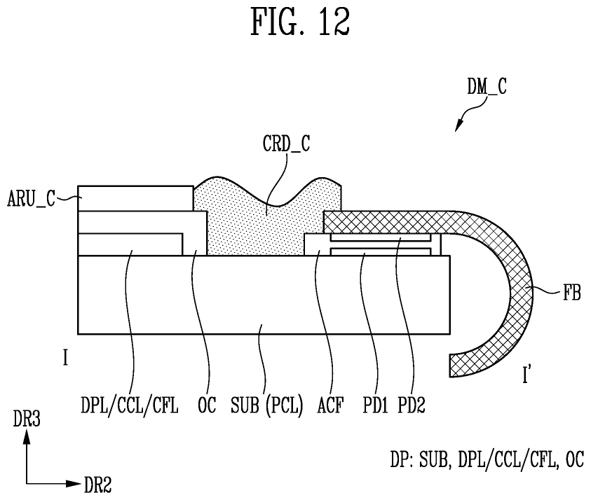

FIG. 12 is a schematic cross-sectional view illustrating a comparative embodiment of the display module taken along line I-I′ of FIG. 2.

Referring to FIGS. 8 and 12, a display module DM_C of FIG. 12 other than an optical layer ARU_C and a protective layer CRD_C is similar to the display module DM of FIG. 8; therefore, repetitive explanation thereof will be omitted.

The optical layer ARU_C may partially overlap the overcoat layer OC, and may not overlap the circuit board FB. To form the protective layer CRD_C, the optical layer ARU may be disposed to cover only a portion of the display panel DP. The circuit board FB may be exposed from the optical layer ARU.

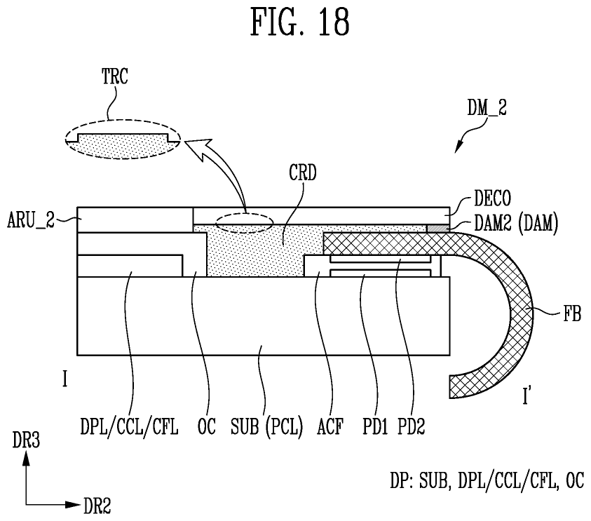

To form the protective layer CRD_C, a resin solution may be supplied to a side of the optical layer ARU_C, e.g., a space between the overcoat layer OC and the circuit board FB. With improvement in the technology of fabricating the display panel DP, the thickness of the display panel DP (e.g., the display element layer DPL, the overcoat layer OC, and the like) has been reduced, and the amount of resin solution to be supplied to form the protective layer CRD_C may be reduced. For example, it is difficult to uniformly control the thickness (or the height) of the protective layer CRD_C only by reducing an amount of supplied resin solution (e.g., a small amount of resin solution). Hence, it may be difficult to secure the characteristics (e.g., the moisture permeation prevention and the peeling prevention) of the protective layer CRD_C. After the protective layer CRD_C is formed, a decoration film (refer to FIG. 18) may be attached to the protective layer CRD_C and the circuit board FB. Due to the thickness of the protective layer CRD_C which is provided to control the thickness and secure the characteristics of the display module, a step difference between the optical layer ARU_C and the decoration film (e.g., a difference in height between top surfaces thereof) may occur. The step difference may result in a defect of the display module DM_C.

Therefore, the optical layer ARU described with reference to FIGS. 8 and 9 may be disposed to cover the display panel DP and the circuit board FB. A separate hole HOL may be formed in the optical layer ARU. The protective layer CRD may be formed through the hole HOL.

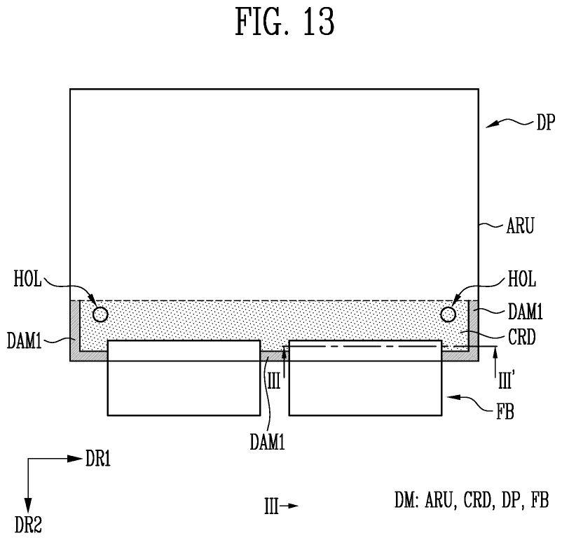

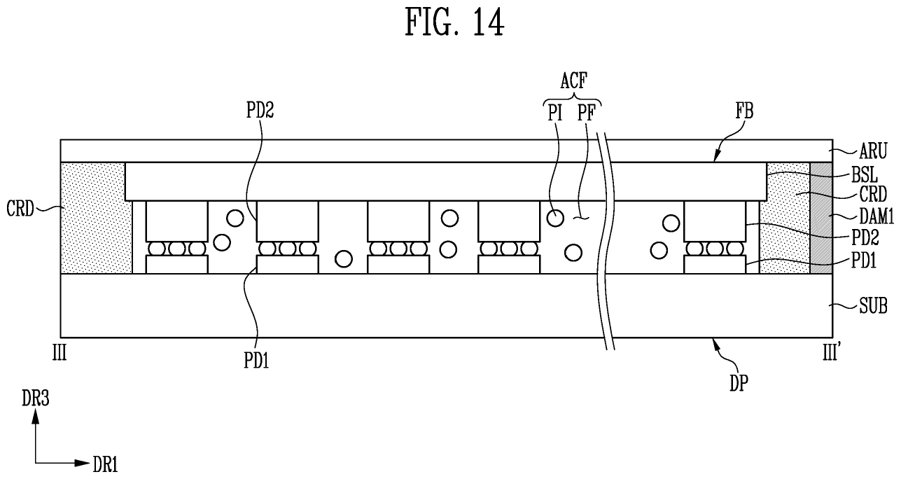

FIG. 13 is a plan view illustrating an embodiment of the display module DM of FIG. 9. FIG. 14 is a schematic cross-sectional view taken along line III-III′ of FIG. 13. FIG. 14 may correspond to FIG. 5. Referring to FIGS. 8, 9, 13, and 14, the display module DM may further include a first dam DAM1.

The first dam DAM1 may be formed along a portion of the edge of the display panel DP. As illustrated in FIG. 13, the first dam DAM1 may be disposed along the portion of the edge of the display panel DP that corresponds to an area (e.g., the pad component PDA of FIG. 2) in which the protective layer CRD is to be formed. The first dam DAM1 may be a structure provided to prevent the resin solution RESIN (refer to FIG. 10) from overflowing from the display panel DP during a process of forming the protective layer CRD. The first dam DAM1 may be formed of a resin, an adhesive tape, or the like, but the material of the first dam DAM1 is not particularly limited. For example, before the optical layer ARU is attached to the display panel DP, a resin may be applied to the portion of the edge of the display panel DP, or an adhesive tape may be attached thereto, thus forming the first dam DAM1. After the first dam DAM1 is formed, the resin solution may be supplied to space more inside (or closer to a center of the display panel DP) than the first dam DAM1 to form the protective layer CRD. In other words, the protective layer CRD may be located more inside (or closer to a center of the display panel DP) than the first dam DAM1. It may be sufficient as long as the first dam DAM1 is provided before the protective layer CRD is formed and a time point at which the first dam DAM1 is formed is not particularly limited.

In an embodiment, the first dam DAM1 may not overlap the circuit board FB, in a plan view. As described with reference to FIG. 8, the optical layer ARU may contact the circuit board FB. The reason for this is because the resin solution may be prevented from overflowing through the space between the optical layer ARU and the circuit board FB. However, the disclosure is not limited thereto. The dam including the first dam DAM1 may overlap the circuit board FB in a plan view (refer to FIG. 18).

As described above, the display module DM may further include the first dam DAM1 disposed along the portion of the edge of the display panel DP, so that the resin solution can be prevented from overflowing from the display panel DP during the process of forming the protective layer CRD. Because the first dam DAM1 is used, a mold may not be needed to be used during the process of fabricating the display module DM.

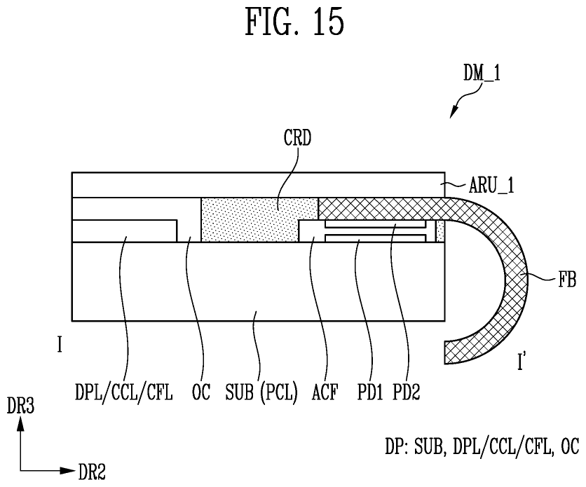

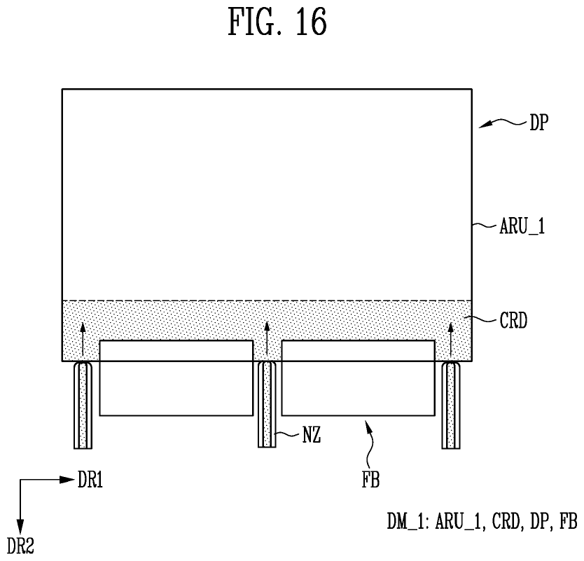

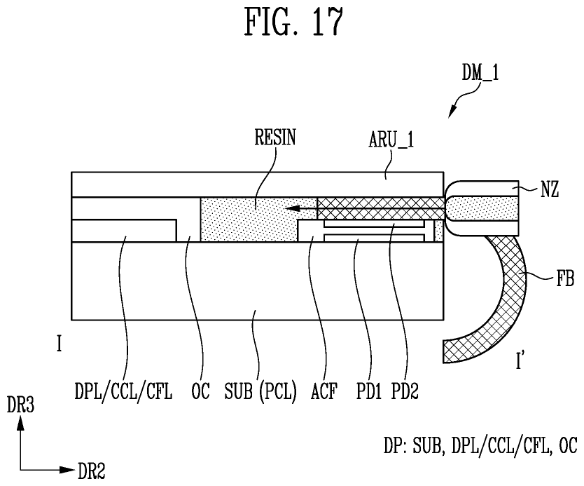

FIG. 15 is a schematic cross-sectional view illustrating another embodiment of the display module taken along line I-I′ of FIG. 2. FIGS. 16 and 17 are views for describing a method of fabricating the display module DM of FIG. 15. FIG. 16 may correspond to FIG. 9.

Referring to FIGS. 8, 9, 15, 16, and 17, a display module DM_1 of FIG. 15 may be substantially identical or similar to the display module DM of FIG. 8; therefore, redundant explanation thereof will be omitted.

The optical layer ARU_1 may not include a hole HOL (refer to FIG. 8).

After the optical layer ARU is attached to the display panel DP, as illustrated in FIG. 16, a printing device (or a nozzle NZ of the printing device) may be located at a position corresponding to space (or a gap) between circuit boards FB. In an embodiment, the printing device may be located between each circuit board FB and a side of the display panel DP (e.g., between a long side of the display panel DP on which the circuit board FB is disposed and a short side thereof). As illustrated in FIG. 17, the printing device may be located at a position corresponding to an area (or gap) between the optical layer ARU and the substrate SUB (or the display panel DP).

The printing device may supply a resin solution RESIN to a space (or gaps) between the circuit boards FB and between the optical layer ARU and the substrate SUB. The resin solution RESIN may be charged into the space between the optical layer ARU and the substrate SUB and the space between the overcoat layer OC and the circuit board FB (or the space between the optical layer ARU, the display panel DP, and the circuit board FB).

Therefore, a light source device, a heating device, or the like may be used to cure the resin solution RESIN. Accordingly, the protective layer CRD may be formed.

The embodiments of FIGS. 13 and 14 (e.g., the first dam DAM1) may be applied to the embodiments of FIGS. 15 to 17.

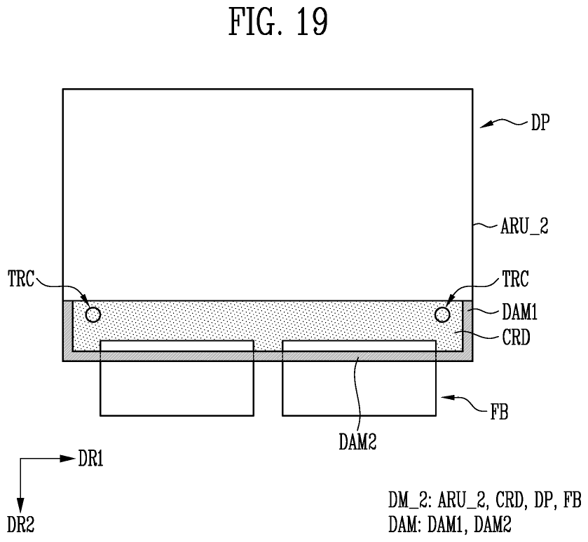

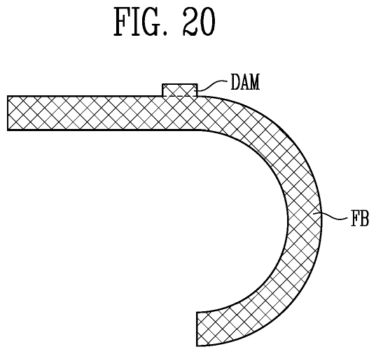

FIG. 18 is a schematic cross-sectional view illustrating another embodiment of the display module taken along line I-I′ of FIG. 2. FIG. 19 is a plan view illustrating the display module of FIG. 18. FIG. 20 is a schematic cross-sectional view illustrating an embodiment of the second dam of FIG. 18.

Referring to FIGS. 8, 9, 18, 19, and 20, a display module DM_2 of FIGS. 18 and 19, other than an optical layer ARU_2, a decoration film DECO, and a dam DAM, is substantially identical or similar to the display module DM of FIGS. 8 and 9; therefore, redundant explanation thereof will be omitted.

The optical layer ARU_2 may partially overlap the overcoat layer OC, and may not overlap the circuit board FB. The optical layer ARU_2 may be disposed to cover only a portion of the display panel DP. The circuit board FB may be exposed from the optical layer ARU_2.

The display module DM_2 may further include a decoration film DECO and a dam DAM.

The decoration film DECO may be disposed on the circuit board FB and a portion of the display panel DP that is exposed from the optical layer ARU_2. The decoration film DECO may be a cover panel (or a chassis) having various colors or patterns to improve aesthetics of the appearance of the display device DD (refer to FIG. 1). The decoration film DECO may cover the circuit board FB and prevent the circuit board FB from being visible. The material of the decoration film DECO is not particularly limited. Various materials may be included in the decoration film DECO within a range capable of satisfying the function of the decoration film DECO.

As illustrated in FIG. 18, the decoration film DECO may contact the optical layer ARU_2 in the second direction DR2. A height of a top surface of the decoration film DECO may be substantially the same as that of a top surface of the optical layer ARU_2. The disclosure is not limited thereto. Because the decoration film DECO is not integrally formed with the optical layer ARU_2, the decoration film DECO may be spaced apart from the optical layer ARU_2 due to a fabrication error, and a step difference between the top surface of the decoration film DECO and the top surface of the optical layer ARU_2 may occur.

In an embodiment, the decoration film DECO may be spaced apart from the circuit board FB in the third direction DR3. For example, the decoration film DECO may be spaced apart from the circuit board FB in the third direction DR3 because of a difference in thickness or the like between the optical layer ARU_2 and the decoration film DECO.

The dam DAM may be formed along a portion of an edge of the display panel DP. As illustrated in FIG. 19, the dam DAM may be disposed along the edge of the display panel DP that corresponds to an area (e.g., the pad component) in which the protective layer CRD is to be formed.

In the same manner as the first dam DAM1 described with reference to FIG. 13, the dam DAM may be a structure provided to prevent the resin solution from overflowing from the display panel DP during a process of forming the protective layer CRD. The dam DAM may be formed of a resin, an adhesive tape, or the like, but the material of the dam DAM is not particularly limited.

In an embodiment, the dam DAM may include a first dam DAM1 and a second dam DAM2. The first dam DAM1 may be substantially identical or similar to the first dam DAM1 of FIG. 13; therefore, redundant explanation thereof will be omitted.

The second dam DAM2 may be provided on the circuit board FB. As illustrated in FIG. 18, the second dam DAM2 may be disposed between the circuit board FB and the optical layer ARU_2. The second dam DAM2 may be formed of a resin, an adhesive tape, or the like, but the material of the second dam DAM2 is not particularly limited. In the case where the second dam DAM2 include the same material as that of the first dam DAM1, the second dam DAM2 and the first dam DAM1 may be simultaneously and integrally formed with each other, but the disclosure is not limited thereto. For example, the first dam DAM1 and the second dam DAM2 may include different materials. Each of the first dam DAM1 and the second dam DAM2 may be individually formed.

In the case where the second dam DAM2 is formed of a resin, an adhesive tape, or the like, the second dam DAM2 along with the protective layer CRD may couple the circuit board FB and the optical layer ARU_2 (or the decoration film DECO) to each other, and may also support the optical layer ARU_2 (or the decoration film DECO).

In an embodiment, as illustrated in FIG. 20, the second dam DAM2 may be integrated with the circuit board FB, or may be a portion protruding from the top surface of the circuit board FB.

The protective layer CRD may be disposed under the decoration film DECO, and may be partially located on the circuit board FB attached to a surface adjacent to a side of the display panel DP so that the protective layer CRD can correspond to the bonding portion of the display panel DP. In an embodiment, the protective layer CRD may partially overlap the overcoat layer OC of the display panel DP in the third direction DR3. The protective layer CRD may be charged into or disposed in the space between the circuit board FB and the decoration film DECO and cover the circuit board FB and the bonding portion of the display panel DP. The protective layer CRD may protect the bonding portion and prevent external water, moisture, or the like from flowing into the bonding portion and permeating to the display panel DP. The protective layer CRD may support the decoration film DECO.

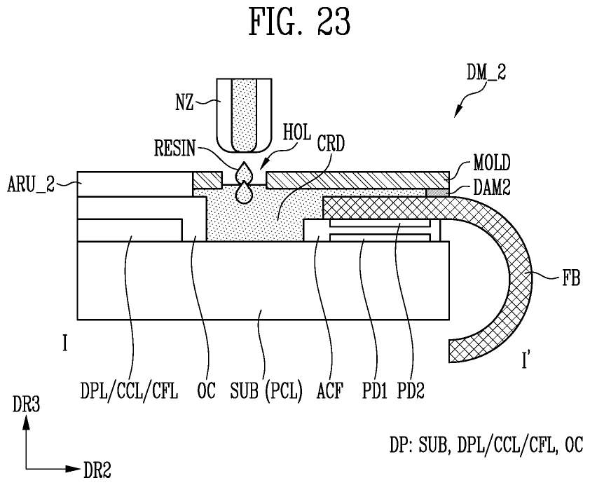

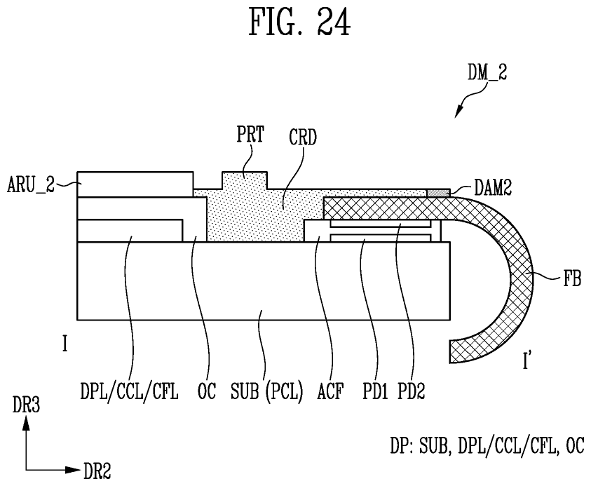

In an embodiment, a trace TRC having an island shape may be formed on the top surface of the protective layer CRD. Although it will be described with reference to FIGS. 23 and 24, during a process of the protective layer CRD using a hole HOL of a mold MOLD (refer to FIG. 23) in a manner as that of the hole HOL of FIG. 8, a protrusion may be formed on the top surface of the protective layer CRD, and the trace TRC of the protective layer CRD may be a trace that remains after the protrusion on the top surface of the protective layer CRD has been removed. For example, in the case where the protrusion of the protective layer CRD is removed by polishing, cutting, or the like, surface characteristics of the trace TRC may differ from that of other portions of the protective layer CRD that do not undergo polishing, cutting, or the like. In other words, the trace TRC of the protective layer CRD may be distinguished from other portions of the protective layer CRD. For example, a location of the trace TRC of the protective layer CRD may correspond to a location of the hole HOL of FIG. 9, but the disclosure is not limited thereto.

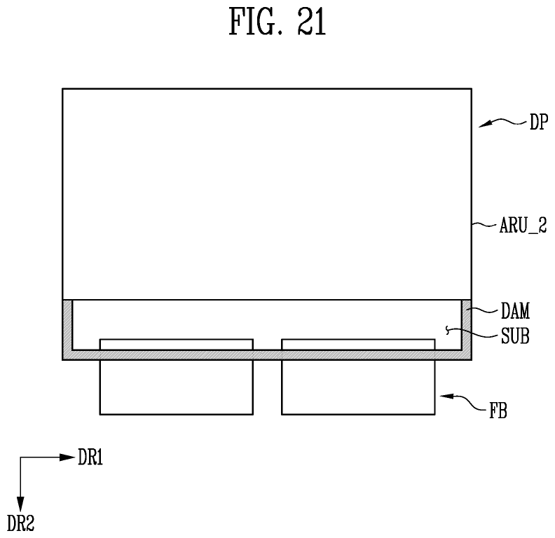

FIGS. 21 to 24 are views for describing a method of fabricating the display module of FIG. 18.

Referring to FIGS. 18 to 24, the display panel DP to which the optical layer ARU_2 is attached may be prepared. The circuit board FB may be bonded to a surface adjacent to a side of the display panel DP.

As illustrated in FIG. 21, the dam DAM may be formed along a portion of an edge of the display panel DP. As described above, the dam DAM may be formed along the portion of the edge of the display panel DP that corresponds to an area (e.g., the pad component) in which the protective layer CRD is to be formed.

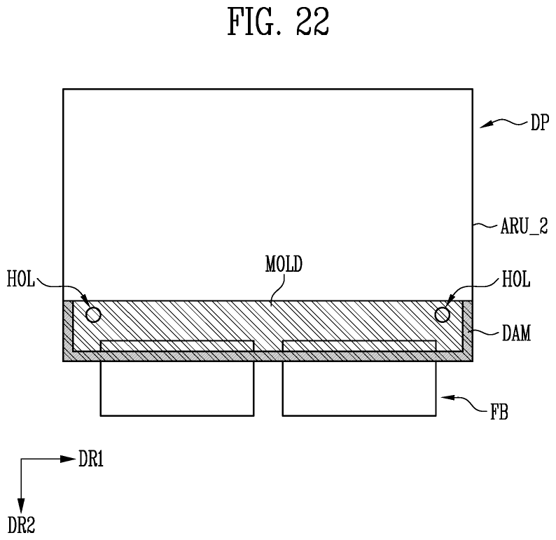

As illustrated in FIGS. 22 and 23, the mold MOLD may be disposed on the circuit board FB and the portion of the display panel DP that is exposed from the optical layer ARU_2. In other words, the mold MOLD may be disposed to cover the circuit board FB. The mold MOLD may include at least one hole HOL (or a through hole, an opening, or a slit) through which the display panel DP (or the substrate SUB) is exposed. The location and size of the hole HOL of the mold MOLD may correspond to the location and size of the hole HOL of the optical layer ARU of FIG. 9, but the disclosure is not limited thereto.

The nozzle NZ of the printing device may be located at a position corresponding to the hole HOL of the mold MOLD. The printing device may supply or apply the resin solution RESIN to the hole HOL of the mold MOLD through the nozzle NZ. The resin solution RESIN that is supplied through the hole HOL of the mold MOLD may be charged into the space between the mold MOLD and the substrate SUB (or the space defined by the mold MOLD, the display panel DP, the circuit board FB, and the dam DAM).

Therefore, a light source device, a heating device, or the like may be used to cure the resin solution RESIN. Accordingly, the protective layer CRD may be formed. In the case where the light source device is used to cure the resin solution RESIN, the mold MOLD may be made of transparent material (e.g., glass) to allow light to pass therethrough so that the light can be irradiated to the resin solution RESIN, but the disclosure is not limited thereto. After the protective layer CRD is formed, the mold MOLD may be removed from the display panel DP.

A protrusion PRT may be formed on the top surface of the protective layer CRD by the resin solution RESIN charged into the hole HOL of the mold MOLD. In other words, corresponding to the hole HOL of the mold MOLD, the protrusion PRT may be formed on the top surface of the protective layer CRD. The protrusion PRT of the protective layer CRD may be removed by polishing, cutting, or the like. The trace TRC formed by removing the protrusion PRT of the protective layer CRD may remain.

The decoration film DECO may be attached onto the protective layer CRD. Accordingly, the display module DM_2 of FIGS. 18 and 19 may be fabricated.

As described above, the protective layer CRD may be formed in the space between the decoration film DECO, the display panel DP, and the circuit board FB through the hole HOL of the mold MOLD. The resin solution RESIN may be sufficiently supplied through the hole HOL of the mold MOLD, so that the thickness of the protective layer CRD can be controlled to be uniform.

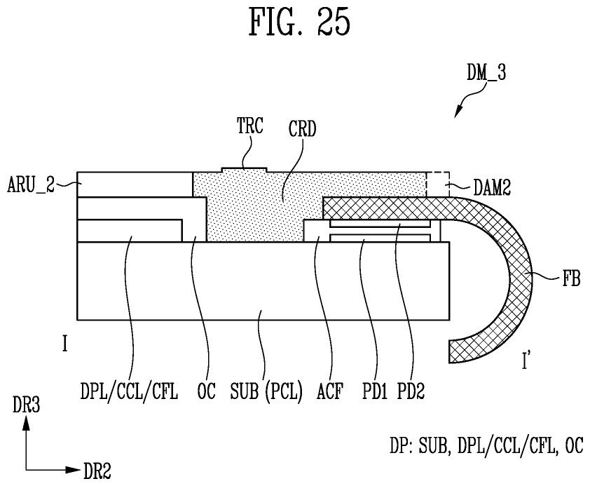

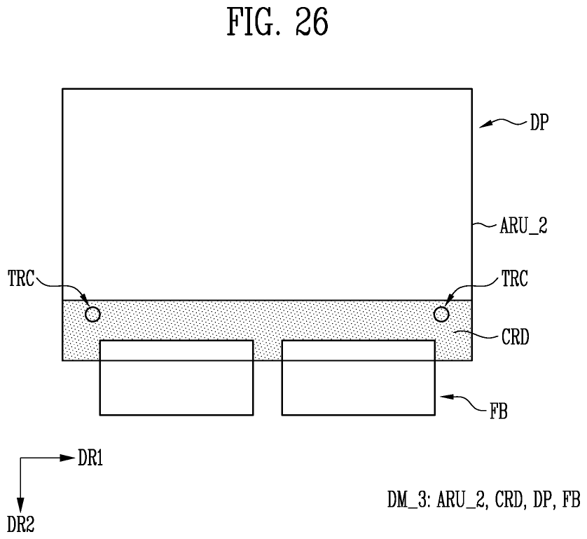

FIG. 25 is a schematic cross-sectional view illustrating another embodiment of the display module taken along line I-I′ of FIG. 2. FIG. 26 is a plan view illustrating the display module of FIG. 25.

Referring to FIGS. 18, 19, 25, and 26, the display module DM_3 of FIGS. 25 and 26 may be substantially equal or similar to the display module DM_2 of FIGS. 18 and 19, other than the decoration film DECO of FIG. 18. Therefore, repetitive explanation thereof will be omitted.

The protective layer CRD may be disposed on the circuit board FB and a portion of the display panel DP that is exposed from the optical layer ARU_2. The height of the top surface of the protective layer CRD may be substantially the same as the height of the top surface of the optical layer ARU_2.

For example, compared to the second dam DAM2 of FIG. 18, the second dam DAM2 may have a relatively large thickness corresponding to the height of the top surface of the protective layer CRD. The mold MOLD of FIG. 23 may be disposed on the second dam DAM2. For example, the mold MOLD of FIG. 23 may be disposed on the optical layer ARU_2 and the dam DAM2, or may be disposed to cover the optical layer ARU_2 and the dam DAM2. The height of the top surface of the protective layer CRD may be substantially the same as the height of the top surface of the optical layer ARU_2. In other words, the top surface of the protective layer CRD and the top surface of the optical layer ARU_2 may be coplanar with each other.

In an embodiment, the protective layer CRD may include a light blocking material. The circuit board FB located under the protective layer CRD may be prevented from being visible.

In an embodiment, the second dam DAM2 may be removed from the display module DM_3. As illustrated in FIG. 26, the display module DM_3 may not include the second dam DAM2.

As described above, in the display module DM_3, only the protective layer CRD may be disposed on the circuit board FB, and the optical layer or the decoration film DECO may not be disposed thereon.

A display device in accordance with an embodiment of the disclosure may include an optical layer which covers a display panel (and a circuit board). A space between the optical layer and the display panel may be filled with a protective layer through at least one hole formed in the optical layer. The protective layer may at least partially cover a bonding portion between the circuit board and the display panel, thus preventing external water, moisture, or the like from being drawn into the bonding portion.

The display device may further include a dam disposed along a portion of an edge of the display panel that corresponds to the bonding portion. The dam may prevent the protective layer from overflowing.

In a method of fabricating a display device in accordance with an embodiment of the disclosure, a resin solution may be supplied into a hole of a mold which covers the display panel (and the circuit board) so that the protective layer may be formed in the space between the display panel and the circuit board. The resin solution may be sufficiently supplied through the hole of the mold, so that the thickness of the protective layer can be controlled to be uniform.

The effects of the disclosure are not limited by the foregoing, and other various effects are anticipated herein.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments.

What is claimed is:

1. A display device comprising:
a display panel including a display area in which pixels are provided, and a non-display area located on a side of the display area;
a circuit board bonded to the display panel in the non-display area, and electrically connected to the pixels;
an optical layer provided on the display panel in the display area; and
a protective layer disposed on the display panel in the non-display area,
wherein a top surface of the protective layer includes a protrusion having an island shape, or a trace formed by removing at least a portion of the protrusion.

2. The display device according to claim 1, wherein the
protective layer includes a resin, and
the optical layer includes an antireflection film.

3. The display device according to claim 1, wherein
the optical layer is provided in the non-display area, and includes a hole corresponding to the protrusion of the protective layer, and
the protective layer is located between the optical layer and the display panel.

4. The display device according to claim 3, wherein a diameter of the hole is less than or equal to approximately 1 mm in a plan view.

5. The display device according to claim 3, wherein the optical layer contacts the circuit board in the non-display area.

6. The display device according to claim 2, wherein a side of the optical layer and a side of the display panel are aligned with each other.

7. The display device according to claim 3, further comprising:
a dam disposed along a portion of a side of the display panel between the display panel and the optical layer,
wherein the protective layer is located closer to a center of the display panel than the dam.

8. The display device according to claim 7, wherein the dam does not overlap the circuit board, in a plan view.

9. The display device according to claim 1, further comprising:
a film provided on the display panel and the circuit board in the non-display area,
wherein the film is located on a side of the optical layer and differs from the optical layer.

10. The display device according to claim 9, further comprising:
a dam disposed along a portion of a side of the display panel between the display panel and the optical layer,
wherein the protective layer is located closer to a center of the display panel than the dam.

11. The display device according to claim 10, wherein the dam comprises a resin or an adhesive tape.

12. The display device according to claim 10, wherein a portion of the dam overlaps the circuit board, in a plan view.

13. The display device according to claim 12, wherein the portion of the dam that overlaps the circuit board is integrated with the circuit board.

14. The display device according to claim 10, wherein the protective layer is charged between the circuit board and the film.

15. The display device according to claim 1, wherein the top surface of the protective layer and a top surface of the optical layer are coplanar with each other.

16. The display device according to claim 15, wherein the protective layer includes a light blocking material.

17. The display device according to claim 1, wherein the display panel comprises:
a display element layer including a light emitting element; and
a light conversion pattern layer disposed on the display element layer and including a quantum dot changing a wavelength of light emitted from the light emitting element,
wherein the light conversion pattern layer is formed through a continuous process on the display element layer.

18. The display device according to claim 17, wherein the light emitting element comprises an inorganic light emitting diode.

19. A method of fabricating a display device, comprising:
bonding circuit boards to a surface adjacent to at least one side of a display panel;
forming a dam along a portion of a side of the display panel;
disposing a mold on the display panel to cover the circuit board;
applying a resin solution between the mold and the display panel through a hole formed in the mold;
forming a protective layer between the mold and the display panel by curing the resin solution; and
removing a protrusion formed on a top surface of the protective layer corresponding to the hole of the mold.

20. The method according to claim 19, further comprising:
attaching a film on the protective layer from which the protrusion is removed.

21. A method of fabricating a display device, comprising:
attaching an optical layer to a display panel to cover circuit boards bonded to a surface adjacent to at least one side of the display panel;
applying a resin solution between the optical layer and the display panel through a gap between the circuit boards; and
forming a protective layer between the optical layer and the circuit board by curing the resin solution.

22. The method according to claim 21, wherein a side of the optical layer and a side of the display panel are aligned with each other.
